(19) United States
(12) Patent Application Publication
(10) Pub. No.: US 2024/0234233 A1
(43) Pub. Date: Jul. 11, 2024

(54) SEMICONDUCTOR DEVICE AND METHOD FOR PRODUCING SEMICONDUCTOR DEVICE

(71) Applicant: ROHM CO., LTD., Kyoto-shi (JP)

(72) Inventors: Naoyuki SANO, Kyoto-shi (JP); Hiroyuki SHINKAI, Kyoto-shi (JP)

(21) Appl. No.: 18/616,773

(22) Filed: Mar. 26, 2024

Related U.S. Application Data
(63) Continuation of application No. PCT/JP2022/036006, filed on Sep. 27, 2022.

(30) Foreign Application Priority Data
Oct. 1, 2021 (JP) 2021-162803

(51) Int. Cl. H01L 23/31; H01L 21/56; H01L 23/00; H01L 23/498

(52) U.S. Cl. CPC H01L 23/3185; H01L 21/56; H01L 23/49838; H01L 24/16; H01L 2224/16225

(57) ABSTRACT

A semiconductor device according to the present invention is provided with: a semiconductor element which has an element front surface, an element back surface, and an element lateral surface; a conductive part that is arranged in a position where the conductive part faces the element back surface, and has a wiring part on which the semiconductor element is mounted; and a sealing resin which seals the semiconductor element and the conductive part. The wiring part has a wiring front surface that faces the element back surface, and a wiring back surface. The conductive part has a terminal part which extends from the wiring back surface in a direction that is opposite to the semiconductor element. The sealing resin covers the element back surface, the element lateral surface and the wiring front surface. The element front surface is exposed without being covered by the sealing resin.

### BACKGROUND

### 1. Field

The present disclosure relates to a semiconductor device and a method for manufacturing a semiconductor device.

### 2. Description of Related Art

Reduction in size of recent electronic apparatus is promoting reduction in size of a semiconductor device used for the electronic apparatus. There have been proposals to use a fan-out type semiconductor device, which includes a semiconductor element having electrodes formed on a back surface, an insulation layer covering the back surface of the semiconductor element, and wiring lines electrically connected to the electrodes and disposed outward from the semiconductor element (refer to, for example, Japanese Laid-Open Patent Publication No. 2021-93454). This allows for reduction in size of the semiconductor device while flexibly corresponding to the shape of wiring patterns of a circuit substrate on which the semiconductor device is mounted.

### BRIEF DESCRIPTION OF DRAWINGS

FIG. 1 is a perspective view showing an embodiment of a semiconductor device.

FIG. 2 is a plan view of the semiconductor device shown in FIG. 1.

FIG. 3 is a back view of the semiconductor device shown in FIG. 1.

FIG. 4 is a cross-sectional view of the semiconductor device taken along line F4-F4 in FIG. 3.

FIG. 5 is an enlarged view of the semiconductor device shown in FIG. 4 including an electrical conductor and its surroundings.

FIG. 6 is a schematic cross-sectional view showing an embodiment of a manufacturing step in a process for manufacturing a semiconductor device.

FIG. 7 is a schematic cross-sectional view showing a manufacturing step following FIG. 6.

FIG. 8 is a schematic cross-sectional view showing a manufacturing step following FIG. 7.

FIG. 9 is a schematic cross-sectional view showing a manufacturing step following FIG. 8.

FIG. 10 is a partial enlarged view of FIG. 9.

FIG. 11 is a schematic cross-sectional view showing a manufacturing step following FIG. 9.

FIG. 12 is a partial enlarged view of FIG. 11.

FIG. 13 is a schematic cross-sectional view showing a manufacturing step following FIG. 11.

FIG. 14 is a schematic cross-sectional view showing a manufacturing step following FIG. 13.

FIG. 15 is a schematic cross-sectional view showing a manufacturing step following FIG. 14.

FIG. 16 is a schematic cross-sectional view showing a manufacturing step following FIG. 15.

FIG. 17 is a schematic cross-sectional view showing a manufacturing step following FIG. 16.

FIG. 18 is a schematic cross-sectional view showing a manufacturing step following FIG. 17.

FIG. 19 is a schematic cross-sectional view showing a manufacturing step following FIG. 18.

FIG. 20 is a schematic cross-sectional view showing a manufacturing step following FIG. 19.

FIG. 21 is an enlarged view of a modified example of a semiconductor device including an electrical conductor and its surroundings.

### DETAILED DESCRIPTION

Embodiments of a semiconductor device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### Embodiments

### Structure of Semiconductor Device

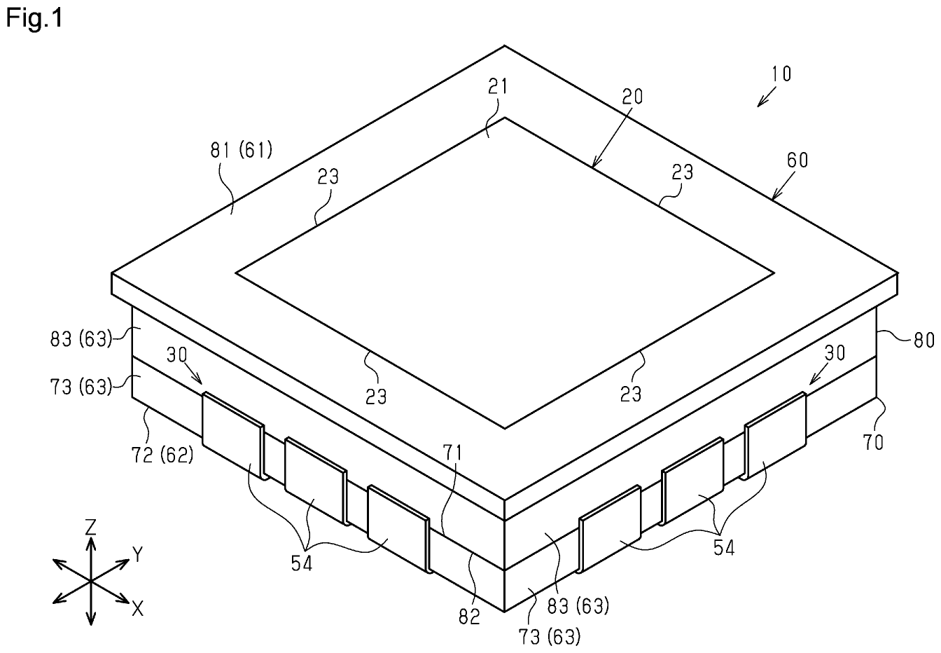

The structure of an embodiment of a semiconductor device will now be described with reference to FIGS. 1 to 5.

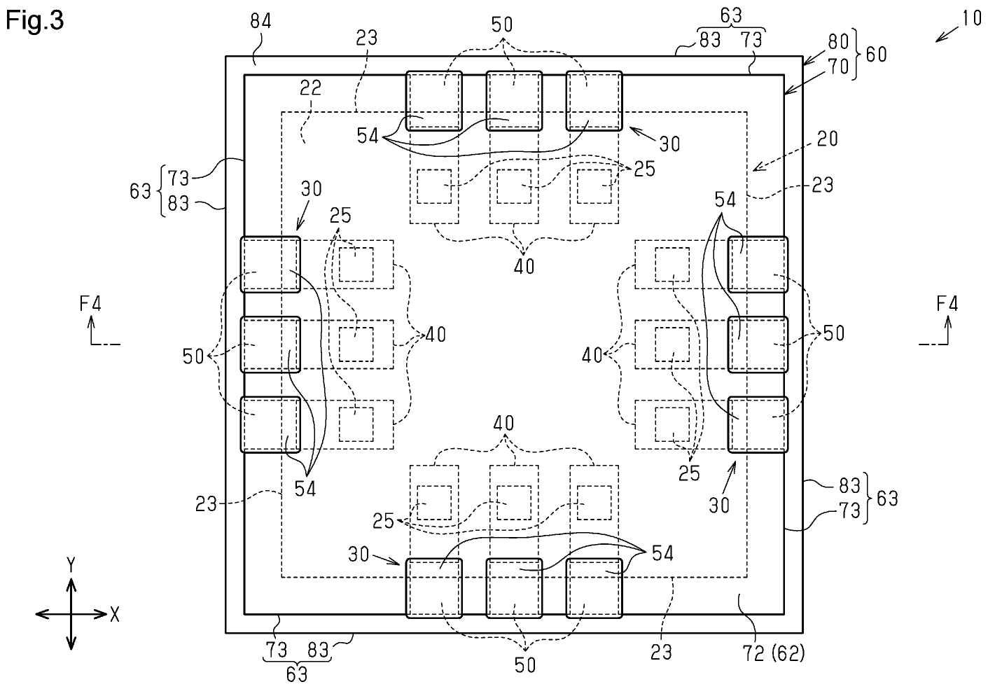

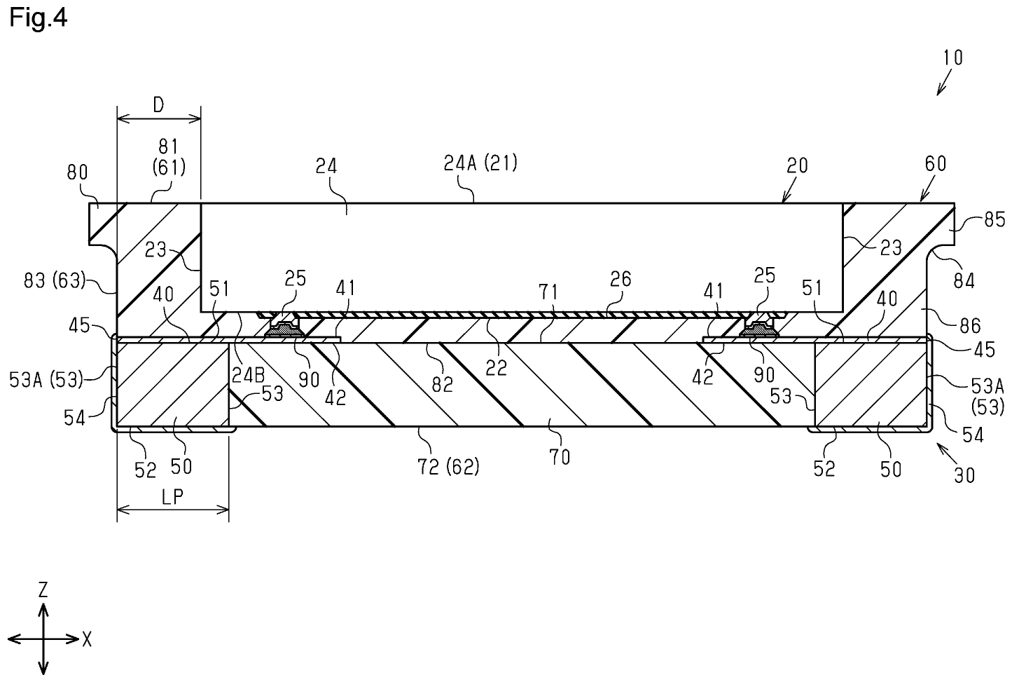

As shown in FIGS. 1 to 3, a semiconductor device 10 includes a semiconductor element 20, electrical conductors 30 electrically connected to the semiconductor element 20, and an encapsulation resin 60 encapsulating the semiconductor element 20 and the electrical conductors 30. The semiconductor device 10 is configured to be surface-mounted on a circuit substrate (not shown) of various electronic apparatuses. The semiconductor device 10 has a package structure of a surface mount type. As shown in FIGS. 3 and 4, the semiconductor device 10 of the present embodiment is a fan-out type in which the electrical conductors 30 include terminals 50 that are located outward from the semiconductor element 20 and configured to be mounted on the circuit substrate.

As shown in FIG. 1, the encapsulation resin 60 includes a device side surface of the semiconductor device 10. The encapsulation resin 60 is rectangular and flat. Thus, the semiconductor device 10 is rectangular and flat. For the sake of brevity, the thickness-wise direction of the encapsulation resin 60 is referred to as the Z-direction. As viewed in the Z-direction, the direction along one side of the semiconductor device 10 orthogonal to the Z-direction is referred to as the X-direction. The direction orthogonal to the X-direction and the Z-direction is referred to as the Y-direction. In the present embodiment, as viewed in the Z-direction, the Y-direction also extends along one side of the semiconductor device 10.

In the present embodiment, the encapsulation resin 60 is square as viewed in the Z-direction. Thus, the semiconductor device 10 is square as viewed in the Z-direction. The shape of the encapsulation resin 60 (the shape of the semiconductor device 10) may be changed in any manner. In an example, as viewed in the Z-direction, the encapsulation resin 60 (the semiconductor device 10) may be rectangular such that the sides in the X-direction are longer than the sides in the Y-direction or the sides in the Y-direction are longer than the sides in the X-direction.

The encapsulation resin 60 includes a resin front surface 61 and a resin back surface 62 opposite to the resin front surface 61. The encapsulation resin 60 includes four resin side surfaces 63 joining the resin front surface 61 and the resin back surface 62 in the Z-direction. In other words, the resin front surface 61, the resin back surface 62, and the four resin side surfaces 63 include outer surfaces of the semiconductor device 10.

The encapsulation resin 60 includes a flat substrate 70 and an encapsulation portion 80 formed on the substrate 70.

The substrate 70 is a support member on which the semiconductor element 20 is mounted and used as a base of the semiconductor device 10. The substrate 70 is formed from an insulative material. In an example, the substrate 70 is formed from a black epoxy resin. The substrate 70 may be formed from any material.

The substrate 70 forms a part of the encapsulation resin 60 located toward the resin back surface 62. The substrate 70 includes a substrate front surface 71 facing in the same direction as the resin front surface 61 and a substrate back surface 72 opposite to the substrate front surface 71. The substrate back surface 72 forms the resin back surface 62. The substrate 70 further includes four substrate side surfaces 73 joining the substrate front surface 71 and the substrate back surface 72 in the Z-direction. The four substrate side surfaces 73 form part of the four resin side surfaces 63 located toward the resin back surface 62.

The encapsulation portion 80 is an encapsulation member that encapsulates the semiconductor element 20. The encapsulation portion 80 is formed from an insulative material. In an example, the encapsulation portion 80 is formed from a black epoxy resin. The encapsulation portion 80 may be formed from any material.

The substrate 70 and the encapsulation portion 80 may be formed from a material that includes, for example, a filler for improving heat dissipation properties. In an example, each of the substrate 70 and the encapsulation portion 80 is formed from a black epoxy resin. However, the ratio of a filler contained in the epoxy resin differs between the substrate 70 and the encapsulation portion 80. Thus, an interface is formed on the boundary between the substrate 70 and the encapsulation portion 80.

The encapsulation portion 80 forms a part of the encapsulation resin 60 located toward the resin front surface 61. The encapsulation portion 80 includes an encapsulation front surface 81 forming the resin front surface 61 and an encapsulation back surface 82 opposite to the encapsulation front surface 81. The encapsulation front surface 81 forms the resin front surface 61. The encapsulation back surface 82 is in contact with the substrate front surface 71 of the substrate 70. The encapsulation back surface 82 of the encapsulation portion 80 and the substrate front surface 71 of the substrate 70 form the interface between the substrate 70 and the encapsulation portion 80. The encapsulation portion 80 further includes four encapsulation side surfaces 83 joining the encapsulation front surface 81 and the encapsulation back surface 82 in the Z-direction. The encapsulation side surfaces 83 are each flush with one of the substrate side surfaces 73 facing in the same direction. The encapsulation side surfaces 83 are each continuous with one of the substrate side surfaces 73 facing in the same direction. The four encapsulation side surfaces 83 form part of the resin side surfaces 63 located toward the resin front surface 61. Thus, the resin side surfaces 63 are formed of the substrate side surfaces 73 and the encapsulation side surfaces 83.

As shown in FIG. 4, the encapsulation portion 80 includes steps 84 that are inwardly recessed from each of the encapsulation side surfaces 83. The steps 84 divide the encapsulation portion 80 into a first encapsulation portion 85 and a second encapsulation portion 86. The first encapsulation portion 85 is part of the encapsulation portion 80 located toward the encapsulation front surface 81. The second encapsulation portion 86 is part of the encapsulation portion 80 located toward the encapsulation back surface 82. More specifically, the first encapsulation portion 85 is located from the steps 84 to the encapsulation front surface 81. The second encapsulation portion 86 is located from the steps 84 to the encapsulation back surface 82. In other words, the second encapsulation portion 86 is recessed inward from the first encapsulation portion 85.

The steps 84 are located overlapping the semiconductor element 20 as viewed in a direction orthogonal to the Z-direction. Thus, the first encapsulation portion 85 and the second encapsulation portion 86 each include a part overlapping the semiconductor element 20 as viewed in a direction orthogonal to the Z-direction. In particular, the first encapsulation portion 85 entirely overlaps the semiconductor element 20 as viewed in a direction orthogonal to the Z-direction.

The semiconductor element 20 encapsulated in the encapsulation portion 80 is, for example, an integrated circuit (IC) such as a large scale integration (LSI). Alternatively, the semiconductor element 20 may be a voltage-controlling element such as a low dropout (LDO) regulator, an amplifying element such as an operational amplifier, or a discrete semiconductor element such as a diode or various sensors.

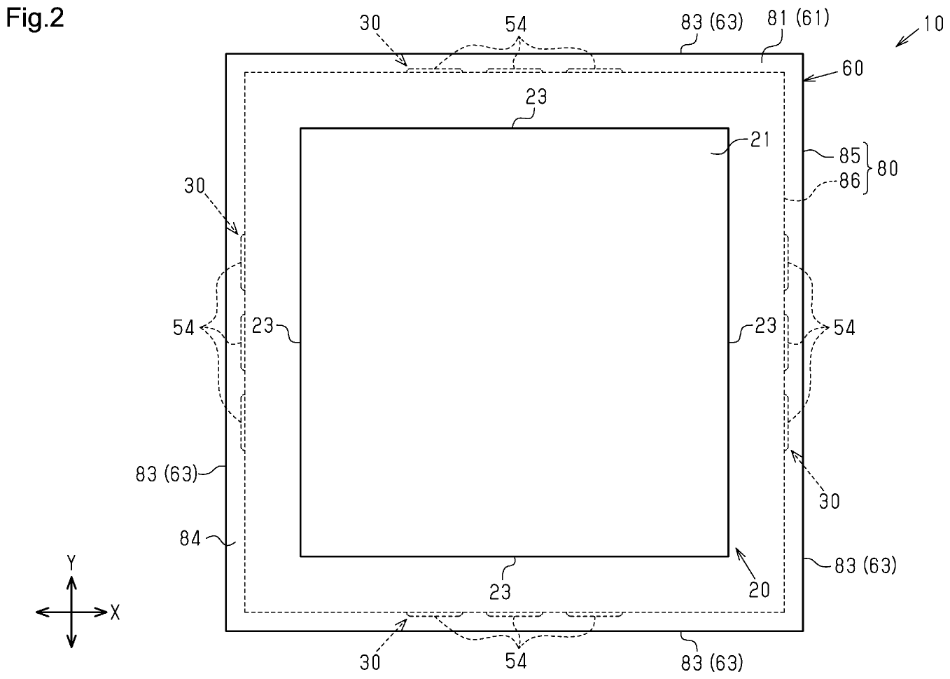

As shown in FIGS. 1 and 4, the semiconductor element 20 is flat. As shown in FIG. 2, in the present embodiment, the semiconductor element 20 is square as viewed in the Z-direction. The shape of the semiconductor element 20 as viewed in the Z-direction may be changed in any manner. In an example, as viewed in the Z-direction, the semiconductor element 20 may be rectangular such that the long sides extend in the X-direction and the short sides extend in the Y-direction or so that the short sides extend in the X-direction and the long sides extend in the Y-direction.

As shown in FIG. 4, the semiconductor element 20 includes an element front surface 21 and an element back surface 22 opposite to the element front surface 21. The element front surface 21 faces in the same direction as the resin front surface 61. In other words, the resin front surface 61 faces in the same direction as the element front surface 21. The element back surface 22 faces in the same direction as the resin back surface 62. In other words, the element back surface 22 is opposed to the substrate front surface 71 of the substrate 70. The semiconductor element 20 further includes four element side surfaces 23 joining the element front surface 21 and the element back surface 22 in the Z-direction.

As shown in FIGS. 3 and 4, the electrical conductors 30 include wiring lines 40 and terminals 50. In the present embodiment, the wiring lines 40 and the terminals 50 are separately provided. The conductors 30 are formed by plating.

The semiconductor element 20 is mounted on the wiring lines 40. The wiring lines 40 are formed on the substrate 70. In other words, the wiring lines 40 are formed on the substrate front surface 71 of the substrate 70. Since the substrate front surface 71 of the substrate 70 is a flat surface orthogonal to the Z-direction, the wiring lines 40 extend in a direction orthogonal to the Z-direction. In other words, the wiring lines 40 are not bent with respect to the Z-direction.

The wiring lines 40 are opposed to the element back surface 22 of the semiconductor element 20. Multiple (in the present embodiment, twelve) wiring lines 40 are arranged. As viewed in the Z-direction, each wiring line 40 extends from a position opposed to the element back surface 22 of the semiconductor element 20 to the outside of the semiconductor element 20. In other words, the wiring line 40 includes an extension extending out from the semiconductor element 20 as viewed in the Z-direction.

As shown in FIG. 4, each wiring line 40 includes a wiring front surface 41 opposed to the element back surface 22 of the semiconductor element 20 and a wiring back surface 42 opposite to the wiring front surface 41. The wiring back surface 42 is in contact with the substrate front surface 71 of the substrate 70.

As shown in FIG. 3, three of the wiring lines 40 are arranged for each of the four resin side surfaces 63 of the encapsulation resin 60. More specifically, as shown in the Z-direction, those of the wiring lines 40 arranged in the vicinity of the resin side surfaces 63 of the encapsulation resin 60 extending in the Y-direction are aligned with each other in the X-direction and spaced apart from each other in the Y-direction. The wiring lines 40 extend in the X-direction and each include an extension extending out from the semiconductor element 20 in the X-direction as viewed in the Z-direction. Also, as shown in the Z-direction, those of the wiring lines 40 arranged in the vicinity of the resin side surfaces 63 of the encapsulation resin 60 extending in the X-direction are aligned with each other in the Y-direction and spaced apart from each other in the X-direction. The wiring lines 40 extend in the Y-direction and each include an extension extending out from the semiconductor element 20 in the Y-direction as viewed in the Z-direction.

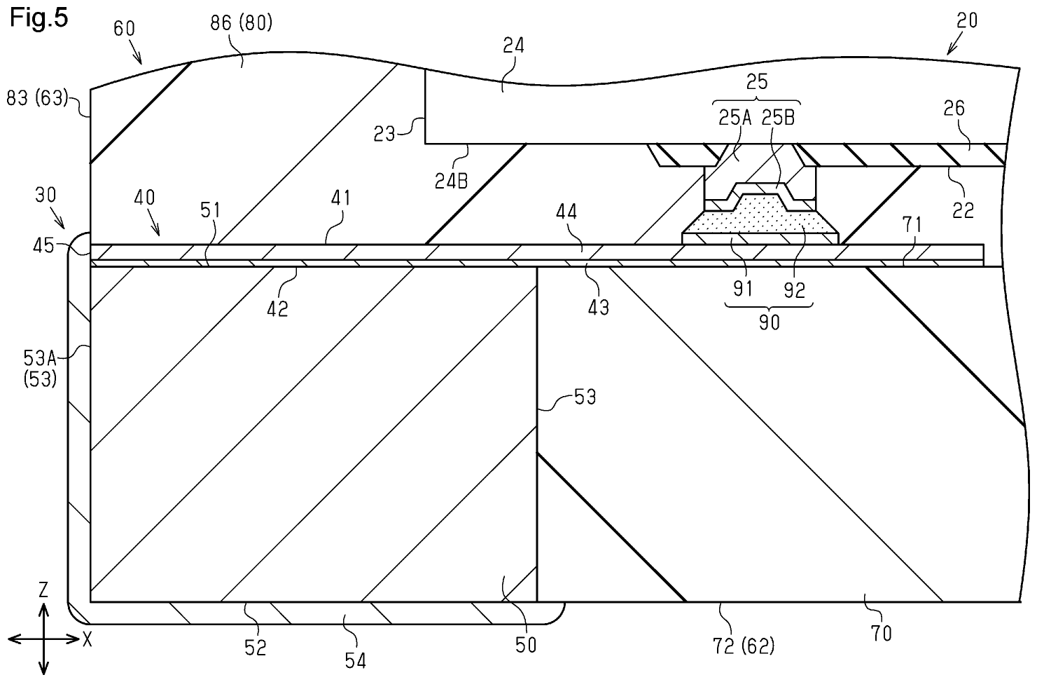

As shown in FIG. 5, the wiring line 40 includes a metal layer 43 and a wiring layer 44.

The metal layer 43 is formed as a seed layer for forming the wiring layer 44. The metal layer 43 is formed from a material including, for example, titanium (Ti). In the present embodiment, the metal layer 43 includes a Ti layer and a copper (Cu) layer in contact with the Ti layer. The metal layer 43 is formed on the substrate front surface 71 of the substrate 70. More specifically, the Ti layer is formed on the substrate front surface 71. The Cu layer is formed on the Ti layer. Thus, the metal layer 43 is formed on the substrate front surface 71. The metal layer 43 includes the wiring back surface 42.

The wiring layer 44 is formed on the metal layer 43. More specifically, the wiring layer 44 is formed on the Cu layer in the metal layer 43. Thus, the wiring line 40 has a stack structure of the metal layer 43 and the wiring layer 44. The wiring layer 44 is formed from, for example, Cu or an alloy including Cu. The wiring layer 44 includes the wiring front surface 41.

Each wiring line 40 extends to the resin side surface 63 corresponding to the wiring line 40 as viewed in the Z-direction. Each wiring line 40 is exposed from the resin side surface 63 corresponding to the wiring line 40. That is, each wiring line 40 includes an exposed wiring side surface 45 exposed from the resin side surface 63 corresponding to the wiring line 40. In other words, the exposed wiring side surface 45 is exposed from the encapsulation side surface 83 of the encapsulation portion 80. In the present embodiment, the exposed wiring side surface 45 is flush with the encapsulation side surface 83 of the encapsulation portion 80. In other words, the exposed wiring side surface 45 is flush with the resin side surface 63 of the encapsulation resin 60.

The resin side surface 63 corresponding to a wiring line 40 refers to the resin side surface 63 located closest to the wiring line 40. The resin side surface 63 corresponding to a wiring line 40 also refers to the resin side surface 63 including the exposed wiring side surface 45 of the wiring line 40.

The terminal 50 extends from the wiring back surface 42 of the wiring line 40 in a direction opposite from the semiconductor element 20. In other words, the terminal 50 extends from the metal layer 43 of the wiring line 40 in a direction opposite from the semiconductor element 20. The terminal 50 is in contact with the wiring line 40. More specifically, the terminal 50 is in contact with the metal layer 43.

As shown in FIG. 3, multiple (in the present embodiment, twelve) terminals 50 are arranged. The terminals 50 are arranged corresponding to the wiring lines 40. Each terminal 50 is square as viewed in the Z-direction. As viewed in the Z-direction, each side of the terminal 50 has a length LP (refer to FIG. 4) in a range of, for example, 100 μm to 200 μm. In the present embodiment, as viewed in the Z-direction, the length LP of each side of the terminal 50 is, for example, 200 μm. The shape of the terminal 50 as viewed in the Z-direction may be changed in any manner. In an example, as viewed in the Z-direction, the terminal 50 may be rectangular and have long sides and short sides.

The terminals 50 are arranged on peripheral edges of the resin back surface 62 of the encapsulation resin 60 (the substrate back surface 72 of the substrate 70). As viewed in the Z-direction, those of the terminals 50 arranged in the vicinity of the resin side surfaces 63 of the encapsulation resin 60 extending in the Y-direction are aligned with each other in the X-direction and spaced apart from each other in the Y-direction. As viewed in the Z-direction, those of the terminals 50 arranged in the vicinity of the resin side surfaces 63 of the encapsulation resin 60 extending in the X-direction are aligned with each other in the Y-direction and spaced apart from each other in the X-direction.

As shown in FIG. 4, each terminal 50 includes a terminal front surface 51 in contact with the wiring back surface 42 of the wiring line 40 and a terminal back surface 52 opposite to the terminal front surface 51. In the present embodiment, the terminal back surface 52 corresponds to “distal surface of terminal.” The terminal 50 further includes four terminal side surfaces 53 joining the terminal front surface 51 and the terminal back surface 52 in the Z-direction.

Each terminal 50 extends through the substrate 70 in the Z-direction. The terminal back surface 52 of the terminal 50 is exposed from the substrate back surface 72 of the substrate 70 in the Z-direction. In the terminal 50, one of the four terminal side surfaces 53 is exposed from the substrate side surface 73 of the substrate 70 (refer to FIG. 3). That is, the terminal 50 is exposed from the resin back surface 62 and the resin side surface 63 of the encapsulation resin 60. Among the four terminal side surfaces 53 of the terminals 50, the terminal side surface 53 exposed from the substrate side surface 73 is referred to as an “exposed terminal side surface 53A.” Thus, the terminal 50 includes the exposed terminal side surface 53A exposed from the resin side surface 63.

The exposed terminal side surface 53A extends on the entirety of the substrate side surface 73 of the substrate 70 in the Z-direction. The exposed terminal side surface 53A is flush with the substrate side surface 73 of the substrate 70. In other words, the exposed terminal side surface 53A is flush with the resin side surface 63 of the encapsulation resin 60. In the present embodiment, as viewed from the resin side surface 63 from which the exposed terminal side surface 53A is exposed, the exposed terminal side surface 53A is rectangular such that the short sides extend in the Z-direction and the long sides extend in a planar direction of the resin side surface 63 orthogonal to the Z-direction.

As viewed in the Z-direction, the exposed terminal side surface 53A is located overlapping the exposed wiring side surface 45 of the wiring line 40 connected to the terminal 50. Thus, the exposed terminal side surface 53A is joined to the exposed wiring side surface 45 in the Z-direction.

Each terminal 50 includes a portion overlapping the semiconductor element 20 as viewed in the Z-direction. In the present embodiment, an end of the terminal 50 located close to the semiconductor element 20 overlaps the semiconductor element 20 as viewed in the Z-direction. However, the end of the terminal 50 located close to the semiconductor element 20 is located outward from electrode pads 25 of the semiconductor element 20 as viewed in the Z-direction.

In the present embodiment, a distance D between an element side surface 23 of the semiconductor element 20 and the resin side surface 63 of the encapsulation resin 60 (the encapsulation side surface 83 of the second encapsulation portion 86 of the encapsulation portion 80) opposed to the element side surface 23 is less than the length LP of one side of the terminal back surface 52 of the terminal 50.

The terminal 50 includes an external electrode 54 formed of a plating layer. When the semiconductor device 10 is mounted on a circuit substrate using a conductive bonding material such as solder or Ag paste, the external electrode 54 is in contact with the conductive bonding material. The external electrode 54 includes metal layers stacked on one another. The metal layers are, for example, a nickel (Ni) layer, a palladium (Pd) layer, and a gold (Au) layer.

The external electrode 54 is arranged to cover the entirety of the terminal back surface 52 and the entirety of the exposed terminal side surface 53A of the terminal 50. That is, in the present embodiment, the semiconductor device 10 has a wettable flank package. As shown in FIG. 3, the external electrode 54 extends out from the terminal back surface 52 of the terminal 50 in the X-direction and the Y-direction. Thus, as viewed in the Z-direction, the area of the external electrode 54 is greater than the area of the terminal back surface 52 of the terminal 50. Although not shown, the external electrode 54 extends out from the exposed terminal side surface 53A of the terminal 50 in the X-direction (Y-direction) and the Z-direction. The external electrode 54 covers the exposed wiring side surface 45 of the wiring line 40.

An example of the structure for connecting the semiconductor element 20 and the electrical conductors 30 will now be described.

As shown in FIG. 4, the semiconductor element 20 includes an element substrate 24, the electrode pads 25, and an insulation film 26. The electrode pads 25 and the insulation film 26 are arranged on the element substrate 24.

The element substrate 24 is a semiconductor substrate and is formed from a material including, for example, silicon (Si). In the present embodiment, the element substrate 24 is a Si substrate. The element substrate 24 includes a front surface 24A and a back surface 24B. The front surface 24A of the element substrate 24 faces in the same direction as the element front surface 21 of the semiconductor element 20. The back surface 24B faces in the same direction as the element back surface 22 of the semiconductor element 20. In the present embodiment, the front surface 24A of the element substrate 24 defines the element front surface 21 of the semiconductor element 20. In the present embodiment, the back surface 24B refers to a surface including a functional element (e.g., transistor) of the semiconductor element 20.

Multiple (in the present embodiment, twelve) electrode pads 25 are arranged. As shown in FIG. 3, three of the electrode pads 25 are arranged for each of the four element side surfaces 23. As viewed in the Z-direction, those of the electrode pads 25 arranged in the vicinity of the element side surfaces 23 of the semiconductor element 20 extending in the Y-direction are aligned with each other in the X-direction and spaced apart from each other in the Y-direction. As viewed in the Z-direction, those of the electrode pads 25 arranged in the vicinity of the element side surfaces 23 of the semiconductor element 20 extending in the X-direction are aligned with each other in the Y-direction and spaced apart from each other in the X-direction.

As shown in FIG. 5, the electrode pad 25 includes a conductor 25A and a barrier layer 25B. The conductor 25A is formed from a material including, for example, Cu. The conductor 25A projects from the back surface 24B of the element substrate 24. The barrier layer 25B includes, for example, a Ni layer. The barrier layer 25B is formed on the conductor 25A to cover the distal surface of the conductor 25A. The barrier layer 25B limits interfusion of the conductor 25A into a bonding portion 90 (solder layer 92), which will be described later. The structure of the barrier layer 25B may be changed in any manner. In an example, the barrier layer 25B may be formed by stacking a Ni layer, a Pd layer, and an Au layer.

The insulation film 26 covers the back surface 24B of the element substrate 24 and exposes the electrode pad 25. The insulation film 26 covers a circumferential portion of the electrode pad 25. In the present embodiment, the insulation film 26 covers an outer circumferential portion of the electrode pad 25 and exposes an inner circumferential portion of the electrode pad 25 as a connection terminal.

The insulation film 26 is formed from a material including, for example, polyimide resin. The material of the insulation film 26 may be changed in any manner. In an example, the insulation film 26 may be formed from a material including silicon nitride (SiN).

The semiconductor element 20 is connected to the wiring front surface 41 of the wiring line 40 by a conductive bonding portion 90. The bonding portion 90 is arranged between the semiconductor element 20 and the wiring line 40. The bonding portion 90 electrically connects the semiconductor element 20 and the wiring line 40. The bonding portion 90 bonds the electrode pad 25 of the semiconductor element 20 and the wiring line 40.

As shown in FIG. 5, the bonding portion 90 includes a barrier layer 91 and a solder layer 92. The barrier layer 91 is formed from a material including Ni. The barrier layer 91 is formed on the wiring front surface 41 of the wiring line 40. The barrier layer 91 is formed on a position of the wiring front surface 41 of the wiring line 40 opposed to the electrode pad 25 of the semiconductor element 20 in the Z-direction. The thickness of the barrier layer 91 (dimension of the barrier layer 91 in the Z-direction) is, for example, in a range of 3 μm to 5 μm.

The solder layer 92 is formed on the barrier layer 91. The solder layer 92 is formed of tin (Sn) or an alloy including Sn. Examples of the alloy including Sn include a tin-silver (Ag)-based alloy and a tin-antimony (Sb)-based alloy. In the present embodiment, the thickness of the solder layer 92 is greater than the thickness of the barrier layer 91.

The solder layer 92 is in contact with the barrier layer 25B of the electrode pad 25 of the semiconductor element 20. Thus, the solder layer 92 is bonded to the electrode pad 25. This connects the electrode pad 25 of the semiconductor element 20 to the bonding portion 90. Thus, the semiconductor element 20 is mounted on the wiring line 40.

The relationship of the semiconductor element 20, the electrical conductors 30, and the encapsulation resin 60 will now be described.

As shown in FIGS. 1 and 2, the element front surface 21 of the semiconductor element 20 is exposed from the encapsulation resin 60 without being covered by the encapsulation resin 60. In the present embodiment, the entirety of the element front surface 21 of the semiconductor element 20 is exposed from the encapsulation resin 60 without being covered by the encapsulation resin 60. As viewed in the Z-direction, the semiconductor element 20 is located in the center of the encapsulation resin 60. In other words, the element side surfaces 23 of the semiconductor element 20 are separated from the resin side surfaces 63 of the encapsulation resin 60 in the X-direction or the Y-direction. In other words, as viewed in the Z-direction, the element front surface 21 of the semiconductor element 20 is surrounded by the resin front surface 61 of the encapsulation resin 60. As viewed in the Z-direction, the resin front surface 61 has the form of a rectangular frame.

The element front surface 21 of the semiconductor element 20 is greater in area than the resin front surface 61 of the encapsulation resin 60. The area of the element front surface 21 of the semiconductor element 20 is less than or equal to twice the area of the resin front surface 61 of the encapsulation resin 60. The ratio of the area of the element front surface 21 of the semiconductor element 20 to the total area of the element front surface 21 of the semiconductor element 20 and the resin front surface 61 of the encapsulation resin 60 may be in a range of 0.6 to 0.7. In the present embodiment, the area of the element front surface 21 of the semiconductor element 20 is approximately 1.5 times the area of the resin front surface 61 of the encapsulation resin 60. That is, in the present embodiment, the ratio of the area of the element front surface 21 of the semiconductor element 20 to the total area of the element front surface 21 of the semiconductor element 20 and the resin front surface 61 of the encapsulation resin 60 is approximately 0.6.

As shown in FIGS. 1, 2, and 4, the encapsulation resin 60 covers the element back surface 22 and the four element side surfaces 23 of the semiconductor element 20. More specifically, the semiconductor element 20 is located closer to the resin front surface 61 than the substrate 70. The encapsulation portion 80 covers the element back surface 22 and the four element side surfaces 23 of the semiconductor element 20.

As shown in FIG. 4, the encapsulation resin 60 covers the wiring front surface 41 of the wiring line 40. More specifically, the encapsulation resin 60 (the encapsulation portion 80) covers a region of the wiring front surface 41 of the wiring line 40 excluding a region in which the bonding portion 90 is arranged. Thus, the wiring front surface 41 of the wiring line 40 is not exposed from the encapsulation resin 60. The encapsulation resin 60 also covers the wiring side surface of the wiring line 40 excluding the exposed wiring side surface 45.

The encapsulation portion 80 is greater in thickness than the substrate 70. In the present embodiment, the substrate 70 is smaller in thickness than the semiconductor element 20. The steps 84 of the encapsulation portion 80 of the encapsulation resin 60 are located overlapping the semiconductor element 20 as viewed in a direction orthogonal to the Z-direction. The first encapsulation portion 85 of the encapsulation resin 60 is smaller in thickness than the second encapsulation portion 86. The first encapsulation portion 85 is smaller in thickness than the semiconductor element 20. The first encapsulation portion 85 is smaller in thickness than the substrate 70.

The thickness of the semiconductor device 10 is less than 450 μm. In the present embodiment, the thickness of the semiconductor device 10 is approximately 350 μm. The thickness of the semiconductor device 10 is specified by the distance between an outer surface of the external electrode 54 facing in the Z-direction and the resin front surface 61 of the encapsulation resin 60 in the Z-direction.

### Semiconductor Device Manufacturing Method

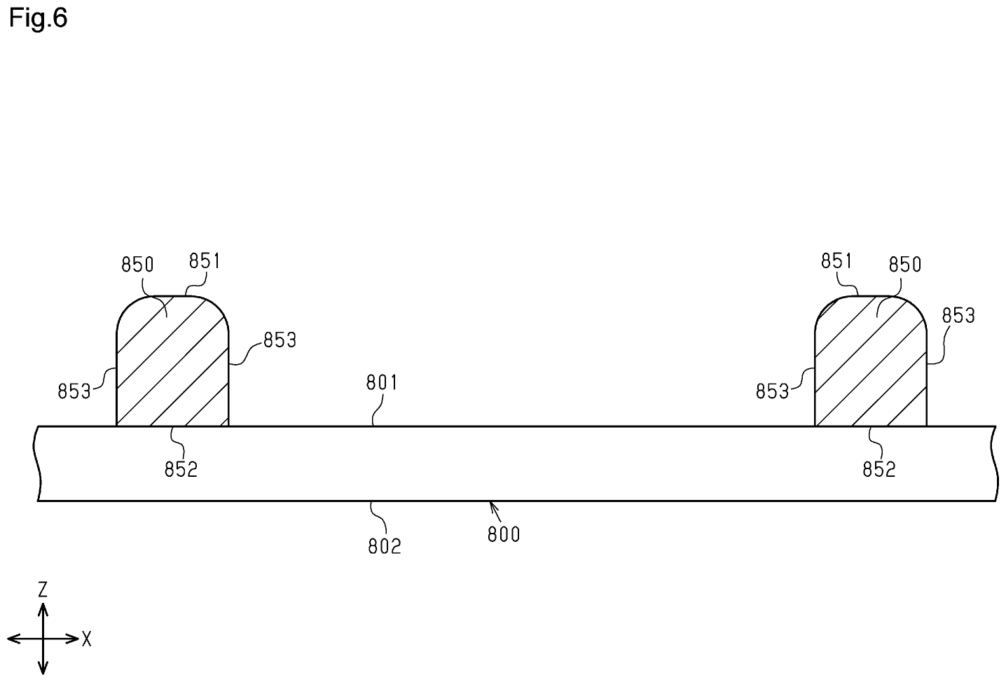

An embodiment of a method for manufacturing the semiconductor device 10 will now be described with reference to FIGS. 6 to 20.

As shown in FIG. 6, the method for manufacturing the semiconductor device 10 includes a step of preparing a semiconductor wafer 800. The semiconductor wafer 800 is formed from, for example, a monocrystalline Si material. The semiconductor wafer 800 includes a wafer front surface 801 and a wafer back surface 802 that face opposite directions in the Z-direction.

The method for manufacturing the semiconductor device 10 subsequently includes a step of forming terminal pillars 850 on the wafer front surface 801 of the semiconductor wafer 800. The terminal pillars 850 form the terminals 50 (refer to FIG. 4) of the semiconductor device 10. The terminal pillars 850 are formed from, for example, Cu or an alloy including Cu. The terminal pillars 850 shown in FIG. 6 are greater in thickness than the terminals 50. Each terminal pillar 850 has the form of, for example, a quadrangular prism. The terminal pillar 850 includes an upper surface 851 facing in the same direction as the wafer front surface 801 of the semiconductor wafer 800 and a lower surface 852 facing a direction opposite from the upper surface 851.

The terminal pillars 850 are formed, for example, through an electrolytic plating process. More specifically, as the step of forming the terminal pillars 850, the method for manufacturing the semiconductor device 10 includes, for example, a step of forming a seed layer, a step of forming a mask on the seed layer through photolithography, and a step of forming a plating metal that contacts the seed layer. Thus, the terminal pillars 850 have a stack structure of the seed layer and the plating metal.

In the step of forming the seed layer, the seed layer is formed on the wafer front surface 801 of the semiconductor wafer 800 through, for example, sputtering. Subsequently, in the step of forming the mask on the seed layer through photolithography, for example, the seed layer is covered by a photosensitive resist layer, and the resist layer undergoes reaction with light and development to form a mask having openings. Subsequently, in the step of forming plating metal that contacts the seed layer, an electrolytic plating process that uses the seed layer as a conductive path is performed so that the plating metal deposits on the surface of the seed layer exposed from the mask. The steps described above form the terminal pillars 850. Subsequent to formation of the terminal pillars 850, the mask is removed. In FIG. 6, for the sake of convenience, the seed layer and the plating metal are not distinguished in the terminal pillars 850.

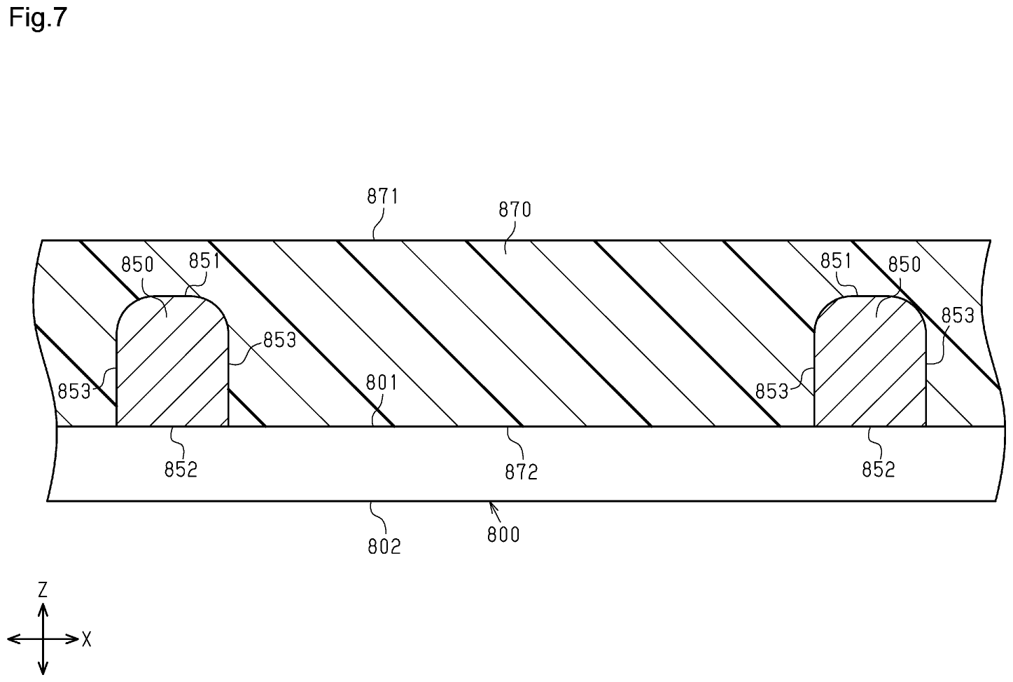

As shown in FIG. 7, the method for manufacturing the semiconductor device 10 includes a step of forming a first resin layer 870. In the step of forming the first resin layer 870, the first resin layer 870 is formed in contact with the wafer front surface 801 of the semiconductor wafer 800 to encapsulate the entirety of the terminal pillars 850. The first resin layer 870 forms the substrate 70 (refer to FIG. 4) of the encapsulation resin 60 of the semiconductor device 10. In an example, the first resin layer 870 is formed from a black epoxy resin. The first resin layer 870 shown in FIG. 7 is greater in thickness than the substrate 70. The first resin layer 870 includes an upper surface 871 and a lower surface 872 that face opposite directions in the thickness-wise direction (Z-direction). The upper surface 871 faces in the same direction as the wafer front surface 801 of the semiconductor wafer 800. The lower surface 872 faces in the same direction as the wafer back surface 802 of the semiconductor wafer 800 and is in contact with the wafer front surface 801 of the semiconductor wafer 800.

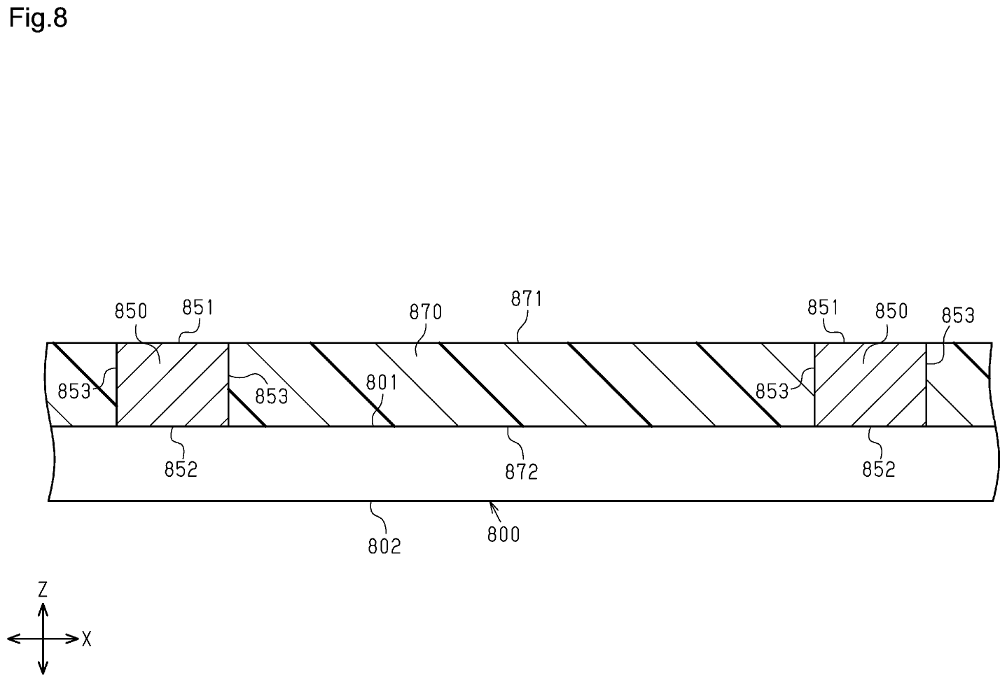

As shown in FIG. 8, the method for manufacturing the semiconductor device 10 includes a step of grinding the first resin layer 870 and the terminal pillars 850. In the step of grinding the first resin layer 870 and the terminal pillars 850, the first resin layer 870 and the terminal pillars 850 are partially ground. In this step, the first resin layer 870 is ground from the upper surface 871 toward the lower surface 872. As a result of the grinding, the terminal pillars 850 are exposed from the upper surface 871 of the first resin layer 870. The upper surface 851 of each terminal pillar 850 is exposed from the upper surface 871 of the first resin layer 870 and forms the terminal front surface 51 (refer to FIG. 4) of the terminal 50. That is, the upper surface 851 of the terminal pillar 850 that has been ground forms the terminal front surface 51 of the terminal 50. In this step, the thickness of the first resin layer 870 becomes equal to the thickness of the substrate 70 of the encapsulation resin 60. All of terminal side surfaces 853 of the terminal pillar 850 are covered by the first resin layer 870. The lower surface 852 of the terminal pillar 850 is covered by the wafer front surface 801 of the semiconductor wafer 800.

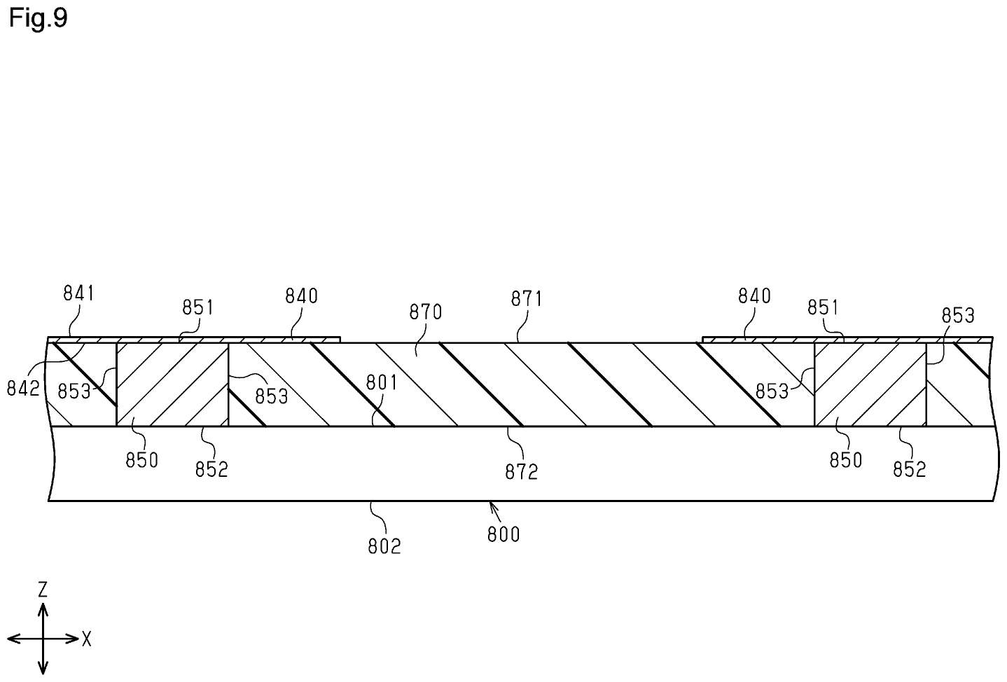

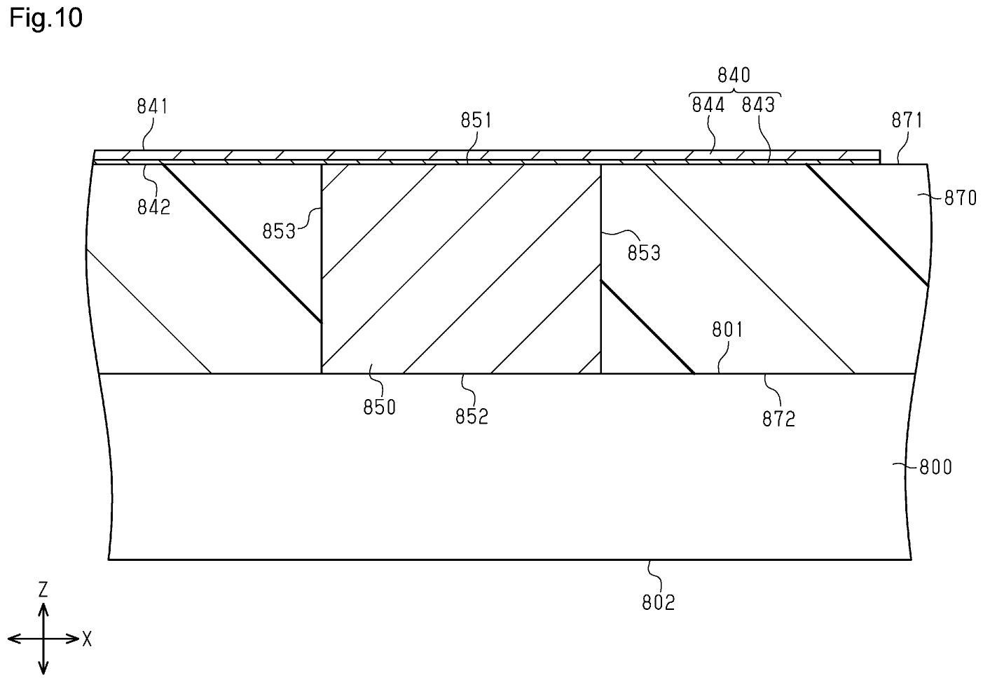

As shown in FIGS. 9 and 10, the method for manufacturing the semiconductor device 10 includes a step of forming a redistribution layer 840. The redistribution layer 840 forms the wiring lines 40 (refer to FIG. 4) of the semiconductor device 10. The redistribution layer 840 is formed on the upper surface 871 of the first resin layer 870 and the upper surface 851 of the terminal pillar 850. The redistribution layer 840 includes a wiring front surface 841 and a wiring back surface 842 that face opposite directions in a thickness-wise direction of the redistribution layer 840 (Z-direction). The wiring front surface 841 faces in the same direction as the upper surface 871 of the first resin layer 870. The wiring back surface 842 faces in the same direction as the lower surface 872 of the first resin layer 870 and is in contact with the upper surface 871 of the first resin layer 870 and the upper surface 851 of the terminal pillar 850.

As shown in FIG. 10, the redistribution layer 840 includes a metal layer 843 and a wiring layer 844. Therefore, the step of forming the redistribution layer 840 includes a step of forming the metal layer 843, a step of forming a mask on the metal layer 843 through photolithography, a step of forming the wiring layer 844 in contact with the metal layer 843, and a step of partially removing the metal layer 843.

In the step of forming the metal layer 843, the metal layer 843 is formed through, for example, sputtering. The metal layer 843 includes, for example, a Ti layer and a Cu layer. In an example of a specific formation process, a Ti layer is formed on the upper surface 871 of the first resin layer 870 and the upper surface 851 of the terminal pillar 850, and a Cu layer is formed in contact with the Ti layer.

Subsequently, in the step of forming the mask on the metal layer 843 through photolithography, for example, the metal layer 843 is covered by a photosensitive resist layer, and the resist layer undergoes exposure and development to form a mask having openings. The openings of the mask correspond to positions where the wiring lines 40 are formed.

In the step of forming the wiring layer 844 on the metal layer 843, for example, an electrolytic plating process that uses the metal layer 843 as a conductive path is performed so that plating metal deposits on the surface of the metal layer 843 exposed from the openings of the mask to form the wiring layer 844. Subsequently, the mask is removed.

In the step of partially removing the metal layer 843, a mask is formed on the wiring layer 844 and the metal layer 843 through photolithography. More specifically, the wiring layer 844 and portions of the metal layer 843 overlapping the wiring layer 844 as viewed in the Z-direction are covered by, for example, a photosensitive resist layer. The resist layer undergoes exposure and development to form a mask having openings. The openings of the mask open portions of the metal layer 843 that do not overlap the wiring layer 844 as viewed in the Z-direction. Subsequently, the metal layer 843 exposed from the openings of the mask is removed. The steps described above form multiple redistribution layers 840 corresponding to the wiring lines 40.

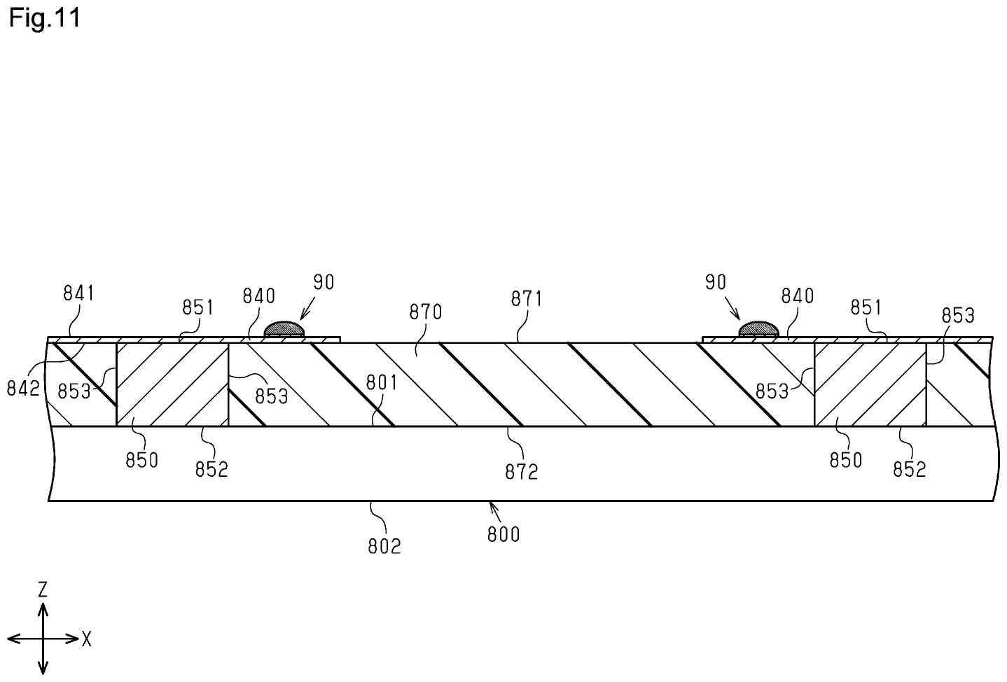

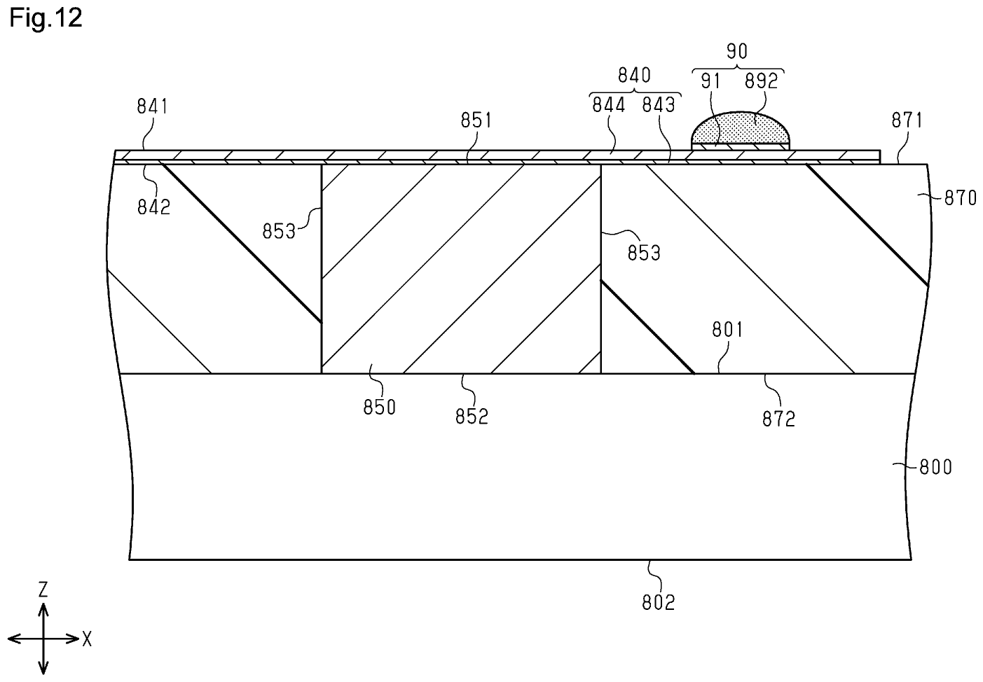

As shown in FIGS. 11 and 12, the method for manufacturing the semiconductor device 10 includes a step of forming the bonding portion 90 on the redistribution layer 840. As shown in FIG. 12, the bonding portion 90 includes the barrier layer 91 and a solder layer 892.

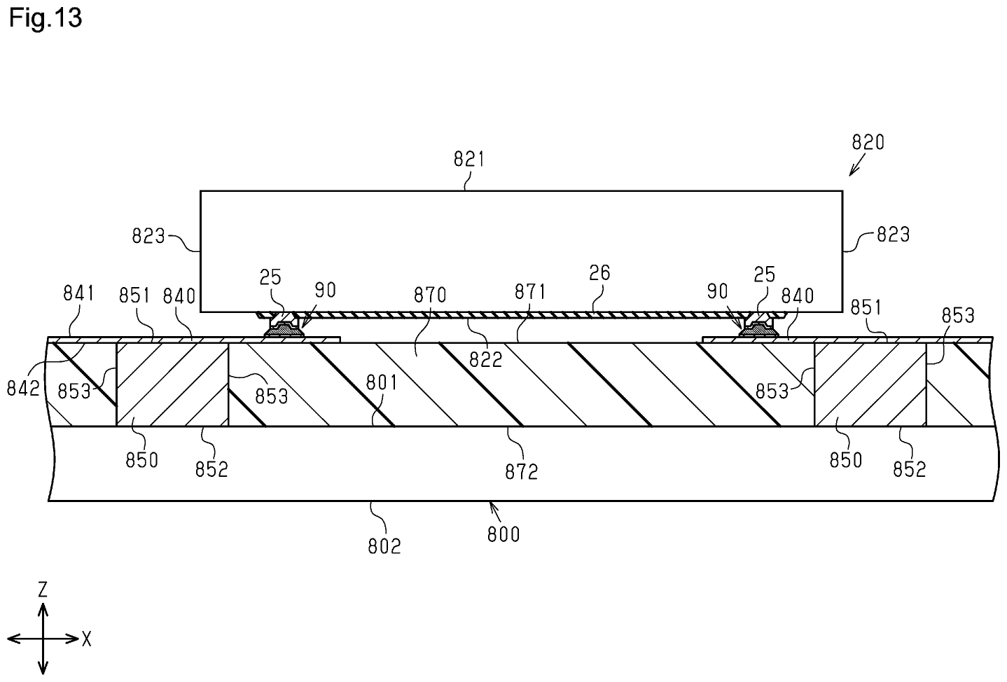

In the step of forming the bonding portion 90 on the redistribution layer 840, the barrier layer 91 is formed on the wiring front surface 841. The barrier layer 91 may be formed through, for example, an electrolytic plating process that uses the redistribution layer 840 as a conductive path. Then, an electrolytic plating process is performed so that an alloy including Sn deposits on the barrier layer 91 as plating metal. This forms the solder layer 892. Subsequently, in a reflow process, the solder layer 892 is melted to smooth a rough surface of the solder layer 892. The smoothing limits formation of voids when the solder layer 892 is bonded to a solder layer of a semiconductor element 820 (refer to FIG. 13). FIGS. 11 and 12 show the solder layer 892 that has undergone the reflow process.

As shown in FIG. 13, the method for manufacturing the semiconductor device 10 includes a step of mounting the semiconductor element 820 on the redistribution layer 840. The semiconductor element 820 is mounted by flip chip bonding (FCB). In this step, the semiconductor element 820 forms the semiconductor element 20 (refer to FIG. 4). The semiconductor element 820 is greater in thickness than the semiconductor element 20. The semiconductor element 820 includes an element front surface 821, an element back surface 822 opposite to the element front surface 821, and four element side surfaces 823 joining the element front surface 821 and the element back surface 822. The element front surface 821 faces in the same direction as the upper surface 871 of the first resin layer 870. The element back surface 822 is opposed to the upper surface 871 of the first resin layer 870. The electrode pads 25 are formed on the element back surface 822.

In the step of mounting the semiconductor element 820 on the redistribution layer 840, for example, an electrolytic plating process is performed so that an alloy including Sn deposits as plating metal on the barrier layer 25B (refer to FIG. 5) of each electrode pad 25 of the semiconductor element 820 to form a solder layer (not shown). The solder layer is formed from, for example, the same material as that forming the solder layer 892 (refer to FIG. 12) of the bonding portion 90. In the same manner as the solder layer 892, the reflow process is performed to smooth the surface of the solder layer of the semiconductor element 820.

Subsequently, for example, a flux is applied to the solder layer of the semiconductor element 820, and then the semiconductor element 820 is mounted on the bonding portion 90 using, for example, a flip-chip bonder. As a result, the semiconductor element 820 is temporarily bonded to the bonding portions 90. Subsequently, the reflow process is performed so that the solder layer 892 of the bonding portion 90 and the solder layer of the semiconductor element 820 change the phase to a liquid state, and then the solder layer 892 and the solder layer of the semiconductor element 820 are cooled and solidified. As a result, the semiconductor element 820 is bonded to the bonding portion 90. Thus, the solder layer 92 of the bonding portion 90 is formed of the solder layer 892 and the solder layer of the semiconductor element 820.

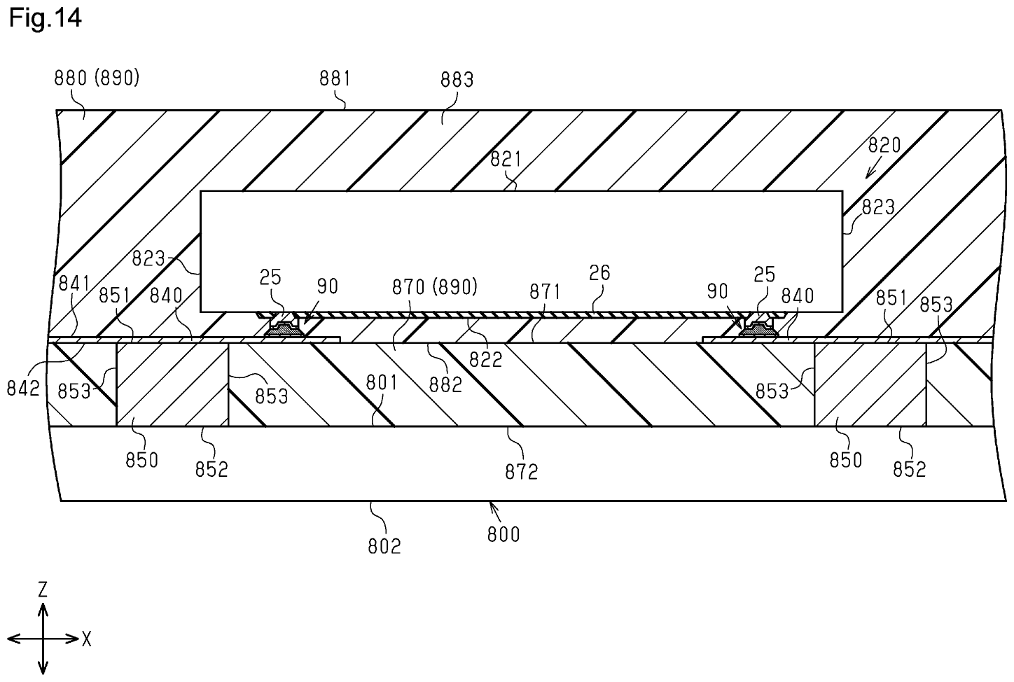

As shown in FIG. 14, the method for manufacturing the semiconductor device 10 includes a step of forming a second resin layer 880 that covers the upper surface 871 of the first resin layer 870 and the semiconductor element 820. The second resin layer 880 forms the encapsulation portion 80 (refer to FIG. 4) of the encapsulation resin 60. The second resin layer 880 is formed from a black epoxy resin. The first resin layer 870 and the second resin layer 880 form an encapsulation resin 890. The encapsulation resin 890 forms the encapsulation resin 60. In the present embodiment, the second resin layer 880 corresponds to “resin layer.”

In the step of forming the second resin layer 880 to cover the upper surface 871 of the first resin layer 870 and the semiconductor element 820, the second resin layer 880 is formed by, for example, compression molding. As a result, the second resin layer 880 encapsulates the semiconductor element 820. The second resin layer 880 includes an element cover 883 covering the element front surface 821 of the semiconductor element 820. The second resin layer 880 includes a resin front surface 881 facing in the same direction as the element front surface 821 of the semiconductor element 820 and a resin back surface 882 opposite to the resin front surface 881.

The second resin layer 880 covers the redistribution layer 840 and is in contact with the upper surface 871 of the first resin layer 870. That is, the second resin layer 880 encapsulates the semiconductor element 820 and the redistribution layer 840. More specifically, the second resin layer 880 covers the element front surface 821, the element back surface 822, and the element side surfaces 823 of the semiconductor element 820 and the wiring front surface 841 of the redistribution layer 840.

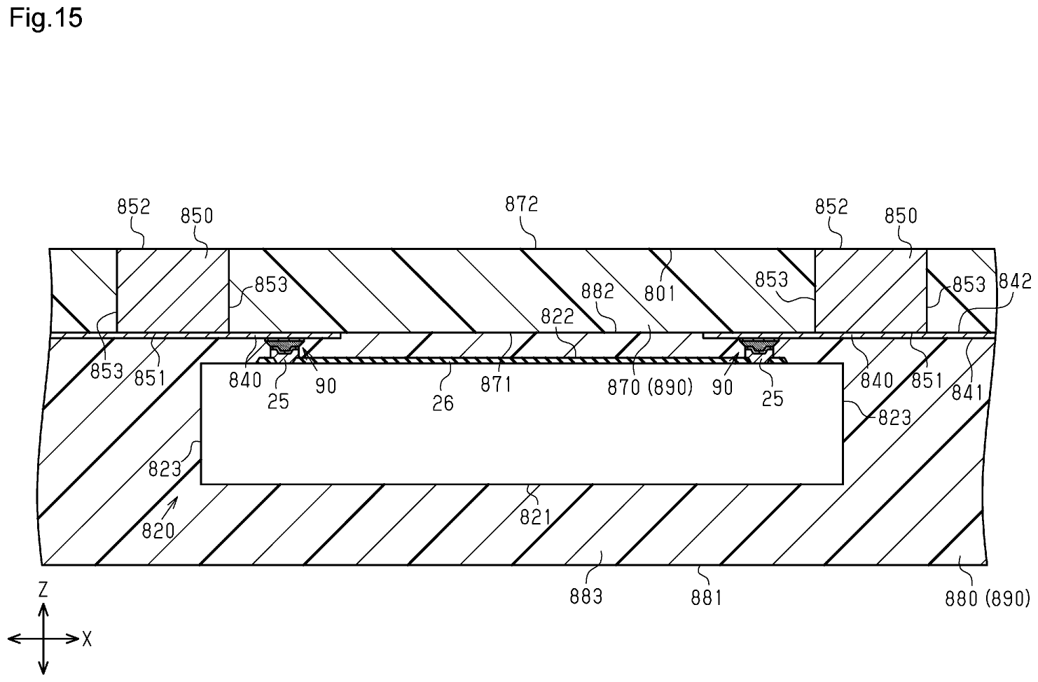

As shown in FIG. 15, the method for manufacturing the semiconductor device 10 includes a step of removing the semiconductor wafer 800. FIG. 15 is an upside-down view of FIG. 14. In the step of removing the semiconductor wafer 800, the semiconductor wafer 800 is removed by, for example, grinding. In this step, the lower surface 872 of the first resin layer 870 and the lower surface 852 of the terminal pillar 850 are also ground. In this case, the seed layer of the terminal pillar 850 may be removed. The means of removing the semiconductor wafer 800 may be changed in any manner. In an example, in the step of removing the semiconductor wafer 800, a separation film may be formed in advance, and the semiconductor wafer 800 may be removed by separation. Subsequent to separation of the semiconductor wafer 800, the lower surface 872 of the first resin layer 870 and the lower surface 852 of the terminal pillar 850 may be ground.

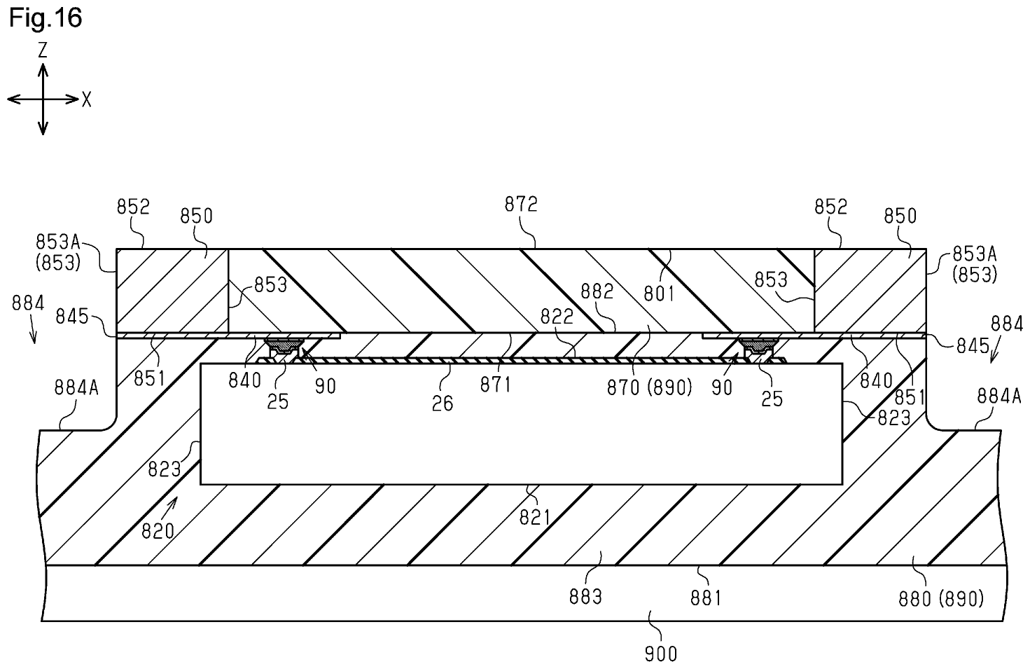

The step of removing the semiconductor wafer 800 is performed between the step of forming the second resin layer 880 and a step of exposing the terminal side surfaces 853 of the terminal pillars 850, which will be described later (refer to FIG. 16). The step of removing the semiconductor wafer 800 may refer to a step that is performed immediately after the step of forming the second resin layer 880.

As shown in FIG. 16, the method for manufacturing the semiconductor device 10 includes a step of exposing the terminal side surfaces 853 of the terminal pillars 850. The step of exposing the terminal side surfaces 853 of the terminal pillars 850 is performed subsequent to the step of forming the second resin layer 880. In this step, among the four terminal side surfaces 853 of the terminal pillar 850, one terminal side surface 853 is exposed. The exposed terminal side surface 853 defines an exposed terminal side surface 853A. The method for manufacturing the semiconductor device 10 further includes a step of exposing side surfaces of the redistribution layers 840. In this step, an exposed wiring side surface 845 is formed in each redistribution layer 840.

In the step of exposing the terminal side surfaces 853 of the terminal pillars 850, dicing tape 900 is applied to the resin front surface 881 of the second resin layer 880. Then, for example, a dicing blade is used to cut from the side of the lower surface 872 of the first resin layer 870 toward the dicing tape 900 in the thickness-wise direction of the second resin layer 880 (Z-direction). In this step, the first resin layer 870 is cut apart, and the second resin layer 880 is partially cut in the thickness-wise direction (half cutting). As a result, grooves 884 are formed in the second resin layer 880. Each groove 884 is formed from the resin back surface 882 of the second resin layer 880 to have a depth in the thickness-wise direction of the second resin layer 880. The groove 884 includes an inner surface defining the encapsulation side surface 83 of the encapsulation portion 80 of the encapsulation resin 60 (refer to FIG. 4). The groove 884 includes a bottom surface 884A located toward the element back surface 822 of the semiconductor element 820 with respect to the element front surface 821.

The first resin layer 870 is cut apart to expose the terminal side surface 853 of the terminal pillar 850. That is, the exposed terminal side surface 853A is formed in the terminal pillar 850. At this time, the terminal pillar 850 is partially cut by the dicing blade. Thus, the terminal pillar 850 and the first resin layer 870 are simultaneously cut by the dicing blade. As a result, the exposed terminal side surface 853A of the terminal pillar 850 is flush with the resin side surface of the first resin layer 870. In other words, a cut mark is formed in the exposed terminal side surface 853A and the resin side surface of the first resin layer 870. While the cutting apart of the first resin layer 870 forms the substrate 70 of the encapsulation resin 60, the partial cutting of the terminal pillar 850 forms the terminal 50. The resin side surface of the first resin layer 870 corresponds to the substrate side surface 73 (refer to FIG. 3) of the substrate 70 and the resin side surface 63 (refer to FIG. 4) of the encapsulation resin 60. That is, a cut mark is formed in the exposed terminal side surface 53A of the terminal 50 and the substrate side surface 73 of the substrate 70 (the resin side surface 63 of the encapsulation resin 60).

The formation of the groove 884 in the second resin layer 880 cuts apart the redistribution layer 840. At this time, the wiring side surface of the redistribution layer 840 is exposed from the groove 884. The wiring side surface of the redistribution layer 840 exposed from the groove 884 is the exposed wiring side surface 845. Thus, the redistribution layer 840 and the second resin layer 880 are simultaneously cut by the dicing blade. As a result, the exposed wiring side surface 845 of the redistribution layer 840 is flush with the inner surface of the groove 884 in the second resin layer 880. A cut mark is formed in the exposed wiring side surface 845 and the resin side surface of the second resin layer 880. The cutting apart of the redistribution layer 840 forms the wiring line 40. Thus, the exposed wiring side surface 845 of the redistribution layer 840 corresponds to the exposed wiring side surface 45 of the wiring line 40. The inner surface of the groove 884 corresponds to the encapsulation side surface 83 (refer to FIG. 4) of the encapsulation portion 80 and the resin side surface 63 of the encapsulation resin 60. That is, a cut mark is formed in the exposed wiring side surface 45 of the wiring line 40 and the encapsulation side surface 83 of the encapsulation portion 80 (the resin side surface 63 of the encapsulation resin 60).

In the step of exposing the terminal side surface 853 of the terminal pillar 850, the terminal pillar 850, the first resin layer 870, the redistribution layer 840, and the second resin layer 880 are cut by the dicing blade in the same step. As a result, the exposed terminal side surface 853A of the terminal pillar 850, the resin side surface of the first resin layer 870, the exposed wiring side surface 845 of the redistribution layer 840, and the inner surface of the groove 884 in the second resin layer 880 are flush with each other. That is, the exposed terminal side surface 53A of the terminal 50, the substrate side surface 73 of the substrate 70, the exposed wiring side surface 45 of the wiring line 40, and the encapsulation side surface 83 of the encapsulation portion 80 are flush with each other.

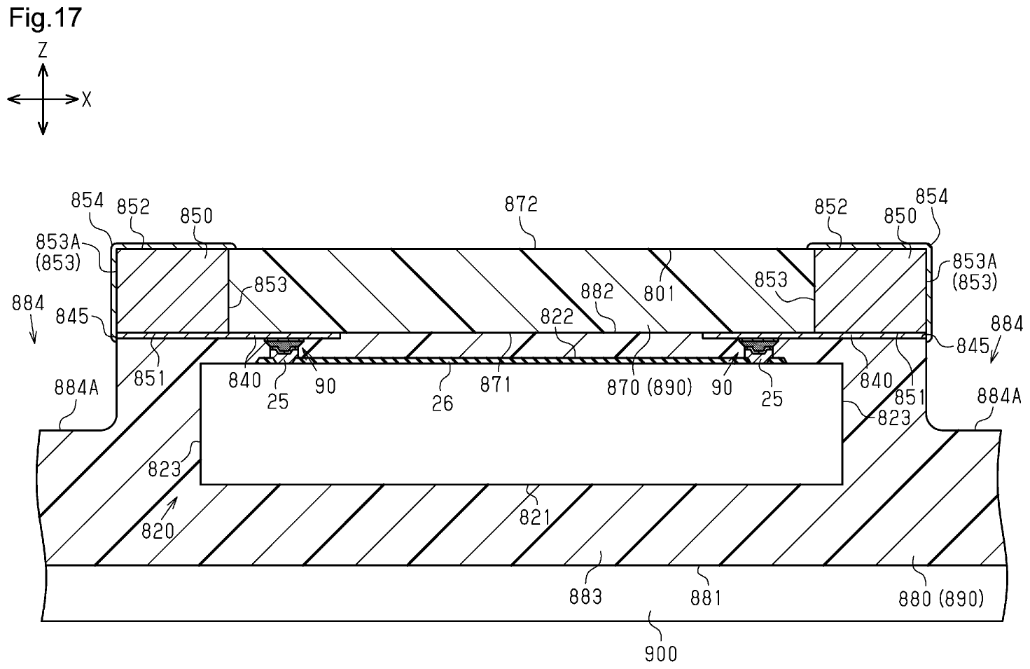

As shown in FIG. 17, the method for manufacturing the semiconductor device 10 includes a step of forming a plating layer 854. The plating layer 854 is formed of plating metal. The plating layer 854 corresponds to the external electrode 54 (refer to FIG. 4). In the step of forming the plating layer 854, an electroless plating process, for example, is performed so that plating metals, which are, for example, Ni, Pd, and Au, deposit in this order to form the plating layer 854. The plating layer 854 covers the exposed terminal side surface 853A and the lower surface 852, which are portions of the terminal pillar 850 exposed from the first resin layer 870, and the exposed wiring side surface 845, which is a portion of the redistribution layer 840 exposed from the second resin layer 880.

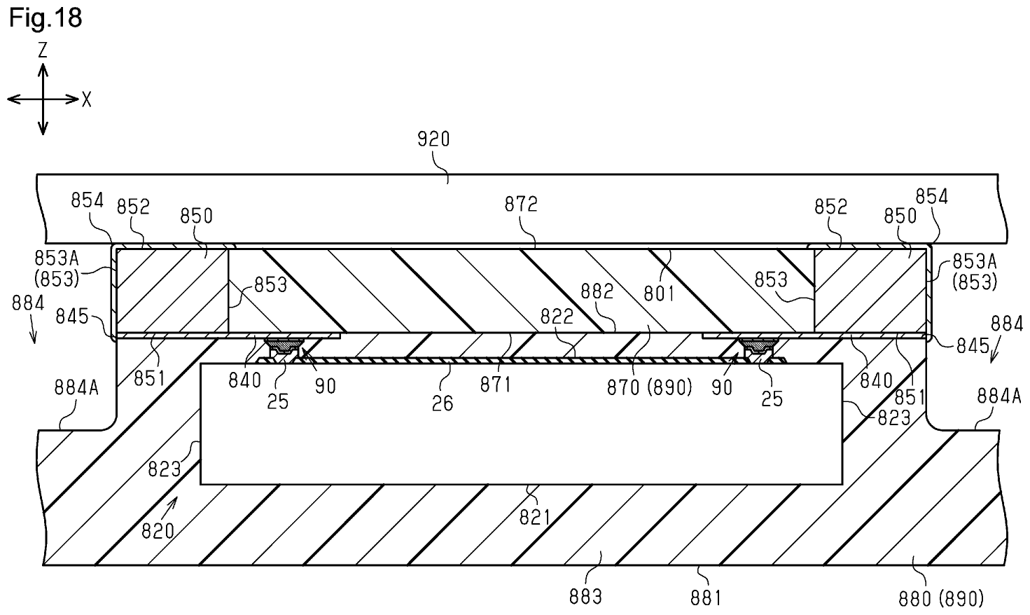

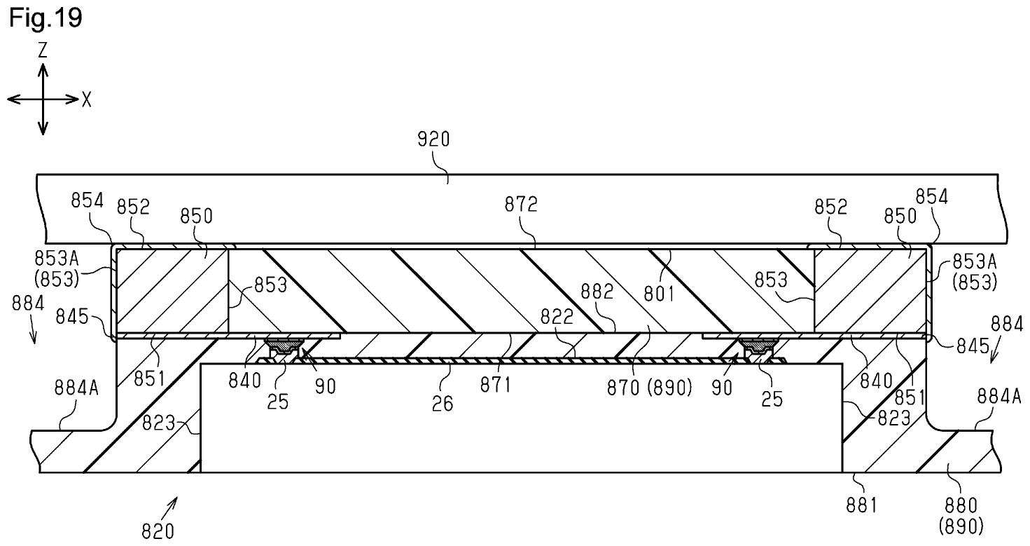

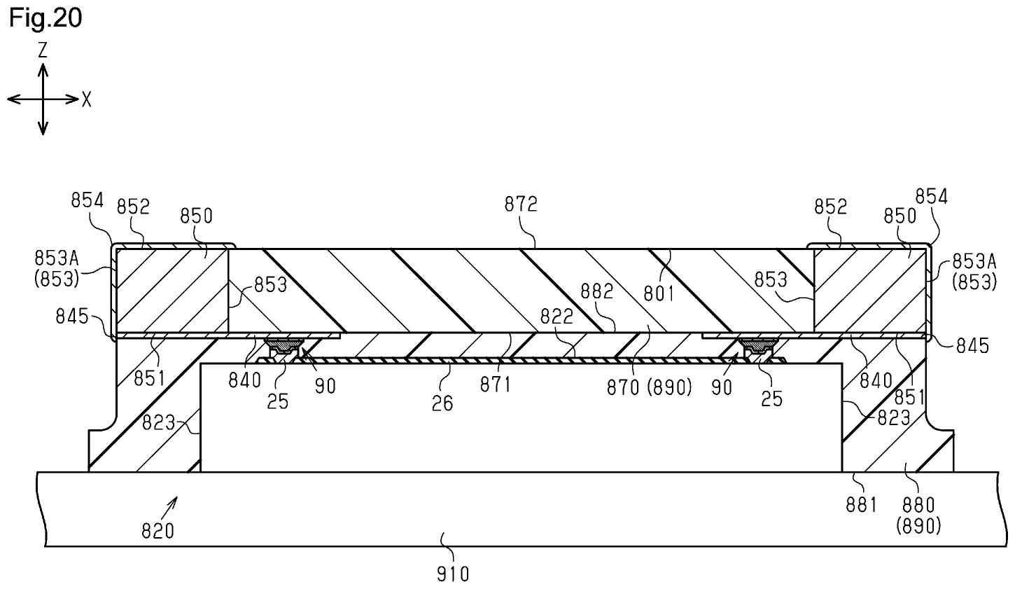

As shown in FIGS. 18 and 19, the method for manufacturing the semiconductor device 10 includes a step of grinding the second resin layer 880. The step of grinding the second resin layer 880 is performed subsequent to the step of forming the plating layer 854. More specifically, the step of grinding the second resin layer 880 is performed between the step of forming the plating layer 854 and a step of cutting apart the second resin layer 880, which will be described later (refer to FIG. 20).

In the step of grinding the second resin layer 880, as shown in FIG. 18, back grinding tape 920 is applied to the side of the lower surface 872 of the first resin layer 870. More specifically, the back grinding tape 920 is applied to a portion of the plating layer 854 covering the lower surfaces 852 of the terminal pillars 850. The back grinding tape 920 may also be applied to the lower surface 872 of the first resin layer 870. Then, as shown in FIG. 19, the second resin layer 880 is ground so that the element cover 883 (refer to FIG. 14) of the second resin layer 880 is removed. That is, the second resin layer 880 is ground from the side of the resin front surface 881 of second resin layer 880. At this time, the second resin layer 880 and the semiconductor element 820 are ground. As a result, the thickness of the second resin layer 880 is equal to the thickness of the encapsulation portion 80. The thickness of the semiconductor element 820 is equal to the thickness of the semiconductor element 20. This forms the semiconductor element 20. In this step, the element front surface 821 of the semiconductor element 820 is exposed from the second resin layer 880 in the thickness-wise direction of the second resin layer 880 (Z-direction). As described above, the step of grinding the second resin layer 880 includes a step of grinding the second resin layer 880 so that the element front surface 821 of the semiconductor element 820 is exposed from the second resin layer 880. After the step of grinding the second resin layer 880, the ground resin front surface 881 of the second resin layer 880 corresponds to the resin front surface 61 of the encapsulation resin 60. The ground element front surface 821 of the semiconductor element 820 corresponds to the element front surface 21 of the semiconductor element 20. Thus, a cut mark is formed in the resin front surface 61 of the encapsulation resin 60 and the element front surface 21 of the semiconductor element 20.

As shown in FIG. 19, the bottom surface 884A of the groove 884 is separated from the resin front surface 881 of the second resin layer 880, which has been ground in the step of grinding the second resin layer 880, toward the resin back surface 882. Also, the bottom surface 884A of the groove 884 is located closer to the resin front surface 881 than the resin back surface 882.

As shown in FIG. 20, the method for manufacturing the semiconductor device 10 includes a step of cutting apart the second resin layer 880 through the groove 884. The step of cutting apart the second resin layer 880 is performed subsequent to the step of grinding the second resin layer 880. In the step of cutting apart the second resin layer 880, dicing tape 910 is applied to the second resin layer 880. Then, a dicing blade having a smaller width than the dicing blade used in the step of exposing the terminal side surface 853 of the terminal pillar 850 (refer to FIG. 16) is used to cut apart the second resin layer 880 from the groove 884 of the second resin layer 880 to the dicing tape 910. More specifically, the step 84 is formed by cutting from the groove 884 of the second resin layer 880 to the dicing tape 910 using the dicing blade having a smaller width. More specifically, when the bottom surface 884A of the groove 884 forms a portion of the step 84, the step 84 is formed by cutting from the bottom surface 884A of the groove 884 toward the dicing tape 910 with the dicing blade. This forms the encapsulation portion 80 including the first encapsulation portion 85 and the second encapsulation portion 86. The steps described above manufacture the semiconductor device 10.

### Operation

Operation of the semiconductor device 10 of the present embodiment will be described.

As shown in FIGS. 1, 2, and 4, the element front surface 21 of the semiconductor element 20 is exposed from the resin front surface 61 of the encapsulation resin 60. That is, the encapsulation resin 60 is not located on the element front surface 21 of the semiconductor element 20. With this structure, when the semiconductor element 20 produces heat, the heat of the semiconductor element 20 is dissipated from the element front surface 21 to the outside of the semiconductor device 10. Thus, the heat dissipation property of the semiconductor element 20 is improved.

When a heat sink is coupled to the semiconductor device 10, the heat sink may be directly coupled to the element front surface 21 of the semiconductor element 20. Heat transfers from the semiconductor element 20 to the heat sink effectively as compared to a structure in which the encapsulation resin 60 is located between the heat sink and the semiconductor element 20. Thus, the heat dissipation property of the semiconductor element 20 is improved.

### Advantages

The semiconductor device 10 of the present embodiment has the following advantages.

(1) The semiconductor device 10 includes the semiconductor element 20, the electrical conductor 30, and the encapsulation resin 60. The semiconductor element 20 includes the element front surface 21, the element back surface 22 opposite to the element front surface 21, and the element side surfaces 23 joining the element front surface 21 and the element back surface 22. The electrical conductor 30 is opposed to the element back surface 22 and includes the wiring line 40 on which the semiconductor element 20 is mounted. The encapsulation resin 60 encapsulates the semiconductor element 20 and the electrical conductor 30. The wiring line 40 includes the wiring front surface 41 opposed to the element back surface 22 and the wiring back surface 42 opposite to the wiring front surface 41. The electrical conductor 30 includes the terminal 50 extending from the wiring back surface 42 in a direction opposite from the semiconductor element 20. The encapsulation resin 60 covers the element back surface 22, the element side surfaces 23, and the wiring front surface 41. The element front surface 21 is exposed without being covered by the encapsulation resin 60.

This structure facilitates dissipation of heat of the semiconductor element 20 directly from the element front surface 21 to the outside of the semiconductor device 10 as compared to a structure in which the element front surface 21 of the semiconductor element 20 is covered by the encapsulation resin 60. Thus, the heat dissipation property of the semiconductor device 10 is improved.

In addition, the thickness of the encapsulation resin 60 is reduced as compared to the structure in which the element front surface 21 of the semiconductor element 20 is covered by the encapsulation resin 60. Accordingly, the height of the semiconductor device 10 is reduced.

(2) The encapsulation resin 60 includes the resin front surface 61 facing in the same direction as the element front surface 21 of the semiconductor element 20. The element front surface 21 of the semiconductor element 20 is greater in area than the resin front surface 61.

This structure facilitates dissipation of heat from the semiconductor element 20 to the outside of the semiconductor device 10 as compared to a structure in which the element front surface 21 of the semiconductor element 20 is smaller in area than the resin front surface 61. Thus, the heat dissipation property of the semiconductor device 10 is further improved.

(3) The resin front surface 61 of the encapsulation resin 60 is flush with the element front surface 21 of the semiconductor element 20. The encapsulation resin 60 is formed by compression molding. The resin front surface 61 and the element front surface 21 each include a cut mark.

In a structure in which the semiconductor element 20 projects from the resin front surface 61 of the encapsulation resin 60 or the element front surface 21 of the semiconductor element 20 is recessed from the resin front surface 61, the semiconductor element 20 needs to be avoided when grinding the encapsulation resin 60 (the second resin layer 880). Thus, the step of grinding the second resin layer 880 is complicated.

In this regard, in the present embodiment, the resin front surface 881 of the second resin layer 880 and the element front surface 821 of the semiconductor element 820 are both ground. As a result, the resin front surface 61 (after being ground, the resin front surface 881 of the second resin layer 880) and the element front surface 21 (after being ground, the element front surface 821 of the semiconductor element 820) each have a cut mark, and the resin front surface 61 is flush with the element front surface 21. When the resin front surface 881 of the second resin layer 880 is ground, the semiconductor element 820 does not have to be avoided. This simplifies the manufacturing of a structure in which the element front surface 21 of the semiconductor element 20 is exposed from the resin front surface 61 of the encapsulation resin 60, which is formed by compression molding.

(4) The encapsulation resin 60 includes the resin front surface 61 facing in the same direction as the element front surface 21 of the semiconductor element 20, the resin back surface 62 opposite to the resin front surface 61, and the resin side surfaces 63 joining the resin front surface 61 and the resin back surface 62. The terminal 50 is exposed from the resin back surface 62 and the resin side surface 63.

With this structure, when a conductive bonding material is used to mount the semiconductor device 10 on a circuit substrate, the conductive bonding material contacts the portion of the terminal 50 exposed from the resin side surface 63. The mount state of the semiconductor device 10 on the circuit substrate may be visually checked from the conductive bonding material contacting the portion of the terminal 50 exposed from the resin side surface 63.

In addition, the area of the terminal 50 exposed from the encapsulation resin 60 is increased. This facilitates heat dissipation from the terminal 50. Heat is readily dissipated from the semiconductor element 20 to the outside of the semiconductor device 10 through the wiring line 40 and the terminal 50. Thus, the heat dissipation property of the semiconductor device 10 is further improved.

(5) The wiring line 40 extends in a direction orthogonal to the thickness-wise direction of the encapsulation resin 60 (Z-direction).

This structure limits variations in the position of the wiring line 40 in the Z-direction. Accordingly, variations in the position of the semiconductor element 20 in the Z-direction are limited. Also, when the semiconductor element 20 is mounted on the wiring line 40, inclination of the semiconductor element 20 from a direction orthogonal to the Z-direction is limited.

(6) The wiring line 40 includes the exposed wiring side surface 45 exposed from the resin side surface 63 of the encapsulation resin 60.

With this structure, when a conductive bonding material is used to mount the semiconductor device 10 on a circuit substrate, the conductive bonding material is bonded to the exposed terminal side surface 53A and the exposed wiring side surface 45. Thus, the conductive bonding material is increased in height from the circuit substrate. This facilitates a visual check of the mount state of the semiconductor device 10 on the circuit substrate. In addition, heat is readily dissipated from the semiconductor element 20 to the outside of the semiconductor device 10 through the wiring line 40. Thus, the heat dissipation property of the semiconductor device 10 is further improved.

(7) The distance D between each element side surface 23 of the semiconductor element 20 and the resin side surface 63 of the encapsulation resin 60 (the encapsulation side surface 83 of the second encapsulation portion 86 of the encapsulation portion 80) corresponding to the element side surface 23 is less than the length LP of one side of the terminal back surface 52 of the terminal 50.

This structure ensures the area of the terminal back surface 52 of the terminal 50, which is a mount surface mounted on a land of a circuit substrate when the semiconductor device 10 is mounted on the circuit substrate, while reducing the size of the semiconductor device 10 in a direction orthogonal to the Z-direction.

(8) The method for manufacturing the semiconductor device 10 includes a step of forming the second resin layer 880 that includes a portion of the encapsulation resin 60 and covers the element front surface 821, the element back surface 822, and the element side surfaces 823 of the semiconductor element 820 and the wiring front surface 841 of the redistribution layer 840 and a step of grinding the second resin layer 880 so that the element front surface 821 is exposed from the second resin layer 880.

This structure facilitates dissipation of heat of the semiconductor element 20 directly from the element front surface 21 to the outside of the semiconductor device 10 as compared to a structure in which the element front surface 21 of the semiconductor element 20, which has undergone grinding, is covered by the second resin layer 880. Thus, the heat dissipation property of the semiconductor device 10 is improved.

In addition, the second resin layer 880 is reduced in thickness as compared to a structure in which the element front surface 21 of the semiconductor element 20, which has undergone grinding, is covered by the second resin layer 880. Accordingly, the height of the semiconductor device 10 is reduced.

(9) In the step of forming the second resin layer 880, the second resin layer 880 is formed by compression molding. In the step of grinding the second resin layer 880, the second resin layer 880 and the semiconductor element 820 are ground.

With this structure, when the resin front surface 881 of the second resin layer 880 is ground, the semiconductor element 820 does not have to be avoided. This simplifies the manufacturing of a structure in which the element front surface 821 of the semiconductor element 820 (the element front surface 21 of the semiconductor element 20) is exposed from the resin front surface 881 of the second resin layer 880, which is formed by compression molding.

The second resin layer 880 may be formed by transfer molding, which is a process of forming the second resin layer 880. In transfer molding, resin is forced into the cavity of a mold to form the second resin layer 880. When the resin is forced into, the semiconductor element 820 may be displaced from the redistribution layer 840.

In this regard, when the second resin layer 880 is formed by compression molding as in the present embodiment, there is no flux of resin forming the second resin layer 880. This limits displacement of the semiconductor element 820 from the redistribution layer 840.

(10) The method for manufacturing the semiconductor device 10 includes the step of exposing the terminal side surface 853 of the terminal pillar 850 by forming the groove 884 in the second resin layer 880 to have a depth in the thickness-wise direction of the second resin layer 880 subsequent to the step of forming the second resin layer 880. The method further includes the step of forming the plating layer 854 on the exposed terminal side surface 853 of the terminal pillar 850. The step of grinding the second resin layer 880 is performed subsequent to the step of forming the plating layer 854 on the exposed terminal side surface 853 of the terminal pillar 850.

In this structure, when the second resin layer 880 is reduced in thickness, the plating layer 854 will not be formed on the exposed terminal side surface 853 of the terminal pillar 850. In other words, transportation to a device for forming the plating layer 854 is avoided when the second resin layer 880 is reduced in thickness.

(11) The second resin layer 880 includes the resin front surface 881 facing in the same direction as the element front surface 821 of the semiconductor element 820 and the resin back surface 882 opposite to the resin front surface 881. The groove 884 is formed from the resin back surface 882 to have a depth in the thickness-wise direction of the second resin layer 880. In the step of grinding the second resin layer 880, the resin front surface 881 of the second resin layer 880 is ground. The bottom surface 884A of the groove 884 is separated from the resin front surface 881, which has been ground in the step of grinding the second resin layer 880, toward the resin back surface 882. Also, the bottom surface 884A of the groove 884 is located closer to the resin front surface 881 than the resin back surface 882.

With this structure, even after grinding the resin front surface 881 of the second resin layer 880, the second resin layer 880 is not cut apart by the groove 884. Thus, when multiple semiconductor devices 10 are simultaneously manufactured, subsequent to the step of grinding the resin front surface 881 of the second resin layer 880, an assembled body including the second resin layer 880 is readily transported to a device (dicing device) that is used in the step of cutting apart the second resin layer 880.

(12) The method for manufacturing the semiconductor device 10 includes the step of preparing the semiconductor wafer 800, the step of forming the terminal pillar 850 on the wafer front surface 801 of the semiconductor wafer 800, and the step of forming the first resin layer 870 on the wafer front surface 801 to encapsulate the terminal pillar 850. The second resin layer 880 and the redistribution layer 840 are formed on the upper surface 871 of the first resin layer 870.

In this structure, the wiring front surface 841 of the redistribution layer 840 is covered by the second resin layer 880. In other words, other electrical conductors are not formed on the wiring front surface 841 of the redistribution layer 840. This limits warping of the semiconductor wafer 800 that would be caused by formation of other electrical conductors on the wiring front surface 841 of the redistribution layer 840. Thus, an assembled body including the semiconductor wafer 800 is readily transported to a device used in another step.

(13) The method for manufacturing the semiconductor device 10 includes the step of removing the semiconductor wafer 800. The step of removing the semiconductor wafer 800 is performed between the step of forming the second resin layer 880 and the step of exposing the terminal side surface 53 of the terminal 50. In other words, the step of removing the semiconductor wafer 800 is performed immediately after the step of forming the second resin layer 880.

In this structure, the semiconductor wafer 800 may be warped when the second resin layer 880 is formed. In this regard, the semiconductor wafer 800 is removed immediately after the formation of the second resin layer 880 to limit the effect of warpage of the semiconductor wafer 800 on the second resin layer 880. In addition, the number of times of transporting an assembled body including the warped semiconductor wafer 800 is reduced.

(14) In the step of grinding the second resin layer 880, only the second resin layer 880 and the semiconductor element 820 are ground. In other words, in the step of grinding the second resin layer 880, the redistribution layer 840 and the terminal pillar 850, which are formed from a metal material, are not ground.

With this structure, when a grinder used in the step of grinding the second resin layer 880 includes a grinding stone, the grinding stone does not grind a metal material and grinds only a resin material. This decreases the wear amount of the grinding stone of the grinder. Accordingly, the life of the grinding stone is less likely to shorten.

### Modified Examples

The embodiment described above may be modified as follows. The embodiment and the following modified examples can be combined as long as the combined modifications remain technically consistent with each other.

The relationship of the area of the element front surface 21 of the semiconductor element 20 and the area of the resin front surface 61 of the encapsulation resin 60 may be changed in any manner. In an example, the area of the element front surface 21 of the semiconductor element 20 may be equal to the area of the resin front surface 61 of the encapsulation resin 60. For example, when the difference between the area of the element front surface 21 of the semiconductor element 20 and the area of the resin front surface 61 of the encapsulation resin 60 is within 10% of the area of the element front surface 21 of the semiconductor element 20, it is considered that the area of the element front surface 21 of the semiconductor element 20 is equal to the area of the resin front surface 61 of the encapsulation resin 60. In an example, the area of the element front surface 21 of the semiconductor element 20 may be smaller than the area of the resin front surface 61 of the encapsulation resin 60.

The element front surface 21 of the semiconductor element 20 does not have to be flush with the resin front surface 61 of the encapsulation resin 60. In an example, the semiconductor element 20 may project from the resin front surface 61 of the encapsulation resin 60. More specifically, in the semiconductor element 20, the element front surface 21 and portions of the element side surfaces 23 located close to the element front surface 21 may be exposed from the encapsulation resin 60. This structure increases the heat dissipation property of the semiconductor element 20. In an example, the element front surface 21 of the semiconductor element 20 may be located closer to the resin back surface 62 of the encapsulation resin 60 than the resin front surface 61. In this case, the semiconductor device 10 includes a recess. The element front surface 21 of the semiconductor element 20 forms the bottom surface of the recess in the semiconductor device 10.

The number of the wiring lines 40 and the number of the terminals 50 may be changed in any manner.

The layout of the wiring lines 40 and the terminals 50 may be changed in any manner. In an example, the wiring lines 40 and the terminals 50 may be omitted from the two sides of the semiconductor element 20 in the Y-direction. In this structure, the wiring lines 40 and the terminals 50 are arranged on the two sides of the semiconductor element 20 in the X-direction. In an example, the wiring lines 40 and the terminals 50 may be omitted from the two sides of the semiconductor element 20 in the X-direction. In this structure, the wiring lines 40 and the terminals 50 are arranged on the two sides of the semiconductor element 20 in the Y-direction.

In an example, the terminals 50 may be arranged outside the semiconductor element 20 as viewed in the Z-direction. That is, the terminals 50 do not have to have the portion overlapping the semiconductor element 20 as viewed in the Z-direction.

The shape of the wiring lines 40 as viewed in a direction orthogonal to the Z-direction may be changed in any manner. In an example, the wiring lines 40 may extend in a direction differing from the direction orthogonal to the Z-direction. The wiring lines 40 may include a portion bent in the Z-direction. That is, the wiring lines 40 are not limited to the structure extending in a direction orthogonal to the Z-direction.

The shape of the wiring lines 40 as viewed in the Z-direction is not limited to a linear shape and may be changed in any manner. In an example, the shape of the wiring lines 40 as viewed in the Z-direction may include a bent portion or may curve and extend.

The shape of the terminals 50 as viewed in the Z-direction may be changed in any manner. In an example, some of the terminals 50 may differ from the remaining terminals 50 in the shape as viewed in the Z-direction.

The wiring line 40 may be arranged so as not to be exposed from the resin side surface 63 of the encapsulation resin 60.

The exposed terminal side surface 53A of the terminal 50 does not have to be flush with the resin side surface 63 of the encapsulation resin 60. In an example, the terminal 50 may project from the resin side surface 63 of the encapsulation resin 60. In this case, in the terminal 50, a portion of the terminal front surface 51, a portion of two of the four terminal side surfaces 53 excluding the exposed terminal side surface 53A, and the terminal back surface 52 are exposed from the encapsulation resin 60.

The terminal 50 may be arranged so as not to be exposed from the resin side surface 63 of the encapsulation resin 60.

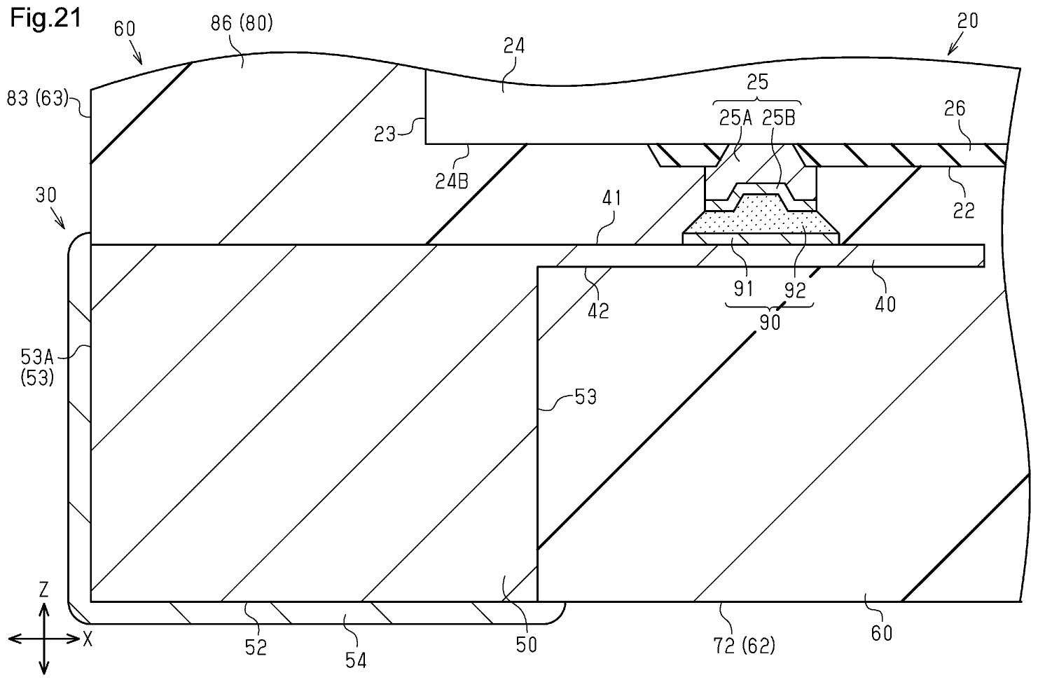

In the embodiment, the wiring line 40 and the terminal 50 of the electrical conductor 30 are separately formed. However, there is no limitation to such a configuration. For example, as shown in FIG. 21, the wiring line 40 and the terminal 50 may be formed integrally with each other. In this case, the wiring lines 40 do not include the metal layer 43. That is, the wiring layer 44 and the terminal 50 are formed as a single member. In addition, the encapsulation resin 60 is formed with no distinction between the substrate 70 and the encapsulation portion 80 (refer to FIG. 4). In the example shown in FIG. 21, the encapsulation resin 60 does not include an interface between the substrate 70 and the encapsulation portion 80. That is, the substrate 70 and the encapsulation portion 80 are formed as a single member.

The steps 84 may be omitted from the encapsulation portion 80 of the encapsulation resin 60. In this case, there may be no distinction between the first encapsulation portion 85 and the second encapsulation portion 86.

Each of the thickness of the substrate 70 of the encapsulation resin 60 and the thickness of the encapsulation portion 80 may be changed in any manner. In an example, the thickness of the substrate 70 may be equal to the thickness of the encapsulation portion 80. The thickness of the substrate 70 may be greater than the thickness of the encapsulation portion 80.

In the step of forming the second resin layer 880, the second resin layer 880 may be formed using a molding process other than compression molding. In an example, in the step of forming the second resin layer 880, the second resin layer 880 may be formed by transfer molding.

In the method for manufacturing the semiconductor device 10, the order of performing the step of grinding the second resin layer 880 may be changed in any manner. In an example, the step of grinding the second resin layer 880 may be performed immediately after the step of forming the second resin layer 880. In an example, the step of grinding the second resin layer 880 may be performed between the step of forming the groove 884 in the second resin layer 880 and the step of forming the plating layer 854 on the terminal 50.

In the step of grinding the second resin layer 880, the semiconductor element 820 does not have to be ground. In other words, in the step of grinding the second resin layer 880, only the second resin layer 880 may be ground. In this case, the semiconductor element 820 corresponds to the semiconductor element 20 of the semiconductor device 10.

The order of performing the step of removing the semiconductor wafer 800 may be changed in any manner. In an example, the step of removing the semiconductor wafer 800 may be performed after the step of exposing the terminal side surface 53 of the terminal 50 or the step of forming the external electrode 54.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In this specification, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### Clause 1

A semiconductor device (10), including:
a semiconductor element (20) including an element front surface (21), an element back surface (22) opposite to the element front surface (21), and an element side surface (23) joining the element front surface (21) and the element back surface (22);
an electrical conductor (30) opposed to the element back surface (22) and including a wiring line (40) on which the semiconductor element (20) is mounted; and
an encapsulation resin (60) encapsulating the semiconductor element (20) and the electrical conductor (30), in which
the wiring line (40) includes a wiring front surface (41) opposed to the element back surface (22) and a wiring back surface (42) opposite to the wiring front surface (41),
the electrical conductor (30) includes a terminal (50) extending from the wiring back surface (42) in a direction opposite from the semiconductor element (20),
the encapsulation resin (60) covers the element back surface (22), the element side surface (23), and the wiring front surface (41), and
the element front surface (21) is exposed without being covered by the encapsulation resin (60).

### Clause 2

The semiconductor device according to clause 1, in which
the encapsulation resin (60) includes a resin front surface (61) facing in a same direction as the element front surface (21) of the semiconductor element (20), and
the element front surface (21) of the semiconductor element (20) is greater in area than the resin front surface (61).

### Clause 3

The semiconductor device according to clause 1 or 2, in which
the encapsulation resin (60) includes a resin front surface (61) facing in a same direction as the element front surface (21) of the semiconductor element (20), and
the resin front surface (61) is flush with the element front surface (21) of the semiconductor element (20).

### Clause 4

The semiconductor device according to clause 3, in which
the element front surface (21) of the semiconductor element (20) and the resin front surface (61) of the encapsulation resin (60) each include a cut mark.

### Clause 5

The semiconductor device according to any one of clauses 1 to 4, in which
the encapsulation resin (60) includes a resin front surface (61) facing in a same direction as the element front surface (21) of the semiconductor element (20), a resin back surface (62) opposite to the resin front surface (61), and a resin side surface (63) joining the resin front surface (61) and the resin back surface (62), and
the terminal (50) is exposed from the resin back surface (62) and the resin side surface (63).

### Clause 6

The semiconductor device according to clause 5, in which
the terminal (50) includes an exposed terminal side surface (53A) exposed from the resin side surface (63), and
the exposed terminal side surface (53A) is flush with the resin side surface (63).

### Clause 7

The semiconductor device according to clause 5 or 6, in which
the wiring line (40) includes an exposed wiring side surface (45) exposed from the resin side surface (63), and
the exposed wiring side surface (45) is flush with the resin side surface (63).

### Clause 8

The semiconductor device according to any one of clauses 1 to 7, in which
the semiconductor element (20) and the wiring line (40) are electrically connected by a conductive bonding portion (90) arranged between the semiconductor element (20) and the wiring line (40), and
the encapsulation resin (60) covers a region of the wiring front surface (41) excluding a region in which the bonding portion (90) is arranged.

### Clause 9

The semiconductor device according to any one of clauses 1 to 8, in which
the wiring line (40) extends in a direction orthogonal to a thickness-wise direction (Z-direction) of the encapsulation resin (60).

### Clause 10

The semiconductor device according to clause 9, in which
the encapsulation resin (60) includes
   a flat substrate (70), and
   an encapsulation portion (80) formed on the substrate (70) to encapsulate the semiconductor element (20),
the substrate (70) includes a substrate front surface (71) facing in a same direction as the element front surface (21) of the semiconductor element (20), and
the wiring line (40) is formed on the substrate front surface (71).

### Clause 11

A method for manufacturing a semiconductor device (10) including: a semiconductor element (820) including an element front surface (821), an element back surface (822) opposite to the element front surface (821), and an element side surface (823) joining the element front surface (821) and the element back surface (822); an electrical conductor (830) opposed to the element back surface (822) and including a wiring line (840) on which the semiconductor element (820) is mounted; and an encapsulation resin (890) encapsulating the semiconductor element (820) and the electrical conductor (830), the wiring line (840) including a wiring front surface (841) opposed to the element back surface (822) and a wiring back surface (842) opposite to the wiring front surface (841), and the electrical conductor (830) including a terminal (850) extending from the wiring back surface (842) in a direction opposite from the semiconductor element (820), the method, including:
forming a resin layer (880) that covers the element front surface (821), the element back surface (822), and the element side surface (823) of the semiconductor element (820) and the wiring front surface (841) of the wiring line (840), the resin layer (880) including a portion of the encapsulation resin (890); and
grinding the resin layer (880) so that the element front surface (821) is exposed from the resin layer (880).

### Clause 12

The method according to clause 11, in which in the forming the resin layer (880), the resin layer (880) is formed by compression molding.

### Clause 13

The method according to clause 11 or 12, in which in the grinding the resin layer (880), the resin layer (880) and the semiconductor element (820) are ground.

### Clause 14

The method according to any one of clauses 11 to 13, further including:
subsequent to the forming the resin layer (880), exposing a side surface (853) of the terminal (850) by forming a groove (884) in the resin layer (880) to have a depth in a thickness-wise direction (Z-direction) of the resin layer (880); and
forming a plating layer (854) on the exposed side surface (853/853A) of the terminal (850),
in which the grinding the resin layer (880) is performed subsequent to the forming the plating layer (854) on the exposed side surface (853/853A) of the terminal (850).

### Clause 15

The method according to clause 14, in which
the resin layer (880) includes a resin front surface (881), facing in a same direction as the element front surface (821) of the semiconductor element (820), and a resin back surface (882) opposite to the resin front surface (881),
the groove (884) is formed from the resin back surface (882) to have a depth in the thickness-wise direction (Z-direction) of the resin layer (880),
in the grinding the resin layer (880), the resin layer (880) is ground from a side of the resin front surface (881), and
the groove (884) includes a bottom surface (884A) separated from the resin front surface (881), which is ground in the grinding the resin layer (880), toward the resin back surface (882).

### Clause 16

The method according to clause 15, further including:
subsequent to the grinding the resin layer (880), cutting apart the resin layer (880) through the groove (884).

### Clause 17

The method according to any one of clauses 11 to 16, further including:
preparing a semiconductor wafer (800);
forming a terminal pillar (850) on a wafer front surface (801) of the semiconductor wafer (800), the terminal pillar (850) including the terminal (850); and
forming a first resin layer (870) on the wafer front surface (800) to encapsulate the terminal pillar (850), in which
the resin layer (880) and the wiring line (840) are formed on an upper surface (871) of the first resin layer (870).

### Clause 18

The method according to clause 17, further including:
removing the semiconductor wafer (800),
in which the removing the semiconductor wafer (800) is performed between the forming the resin layer (880) and the exposing the side surface (853/853A) of the terminal (850).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor device, comprising:
a semiconductor element including an element front surface, an element back surface opposite to the element front surface, and an element side surface joining the element front surface and the element back surface;
an electrical conductor opposed to the element back surface and including a wiring line on which the semiconductor element is mounted; and
an encapsulation resin encapsulating the semiconductor element and the electrical conductor, wherein
the wiring line includes a wiring front surface opposed to the element back surface and a wiring back surface opposite to the wiring front surface,
the electrical conductor includes a terminal extending from the wiring back surface in a direction opposite from the semiconductor element,
the encapsulation resin covers the element back surface, the element side surface, and the wiring front surface, and
the element front surface is exposed without being covered by the encapsulation resin.

2. The semiconductor device according to claim 1, wherein
the encapsulation resin includes a resin front surface facing in a same direction as the element front surface of the semiconductor element, and
the element front surface of the semiconductor element is greater in area than the resin front surface.

3. The semiconductor device according to claim 1, wherein
the encapsulation resin includes a resin front surface facing in a same direction as the element front surface of the semiconductor element, and
the resin front surface is flush with the element front surface of the semiconductor element.

4. The semiconductor device according to claim 3, wherein the element front surface of the semiconductor element and the resin front surface of the encapsulation resin each include a cut mark.

5. The semiconductor device according to claim 1, wherein
the encapsulation resin includes a resin front surface facing in a same direction as the element front surface of the semiconductor element, a resin back surface opposite to the resin front surface, and a resin side surface joining the resin front surface and the resin back surface, and
the terminal is exposed from the resin back surface and the resin side surface.

6. The semiconductor device according to claim 5, wherein
the terminal includes an exposed terminal side surface exposed from the resin side surface, and
the exposed terminal side surface is flush with the resin side surface.

7. The semiconductor device according to claim 5, wherein
the wiring line includes an exposed wiring side surface exposed from the resin side surface, and
the exposed wiring side surface is flush with the resin side surface.

8. The semiconductor device according to claim 1, wherein
the semiconductor element and the wiring line are electrically connected by a conductive bonding portion arranged between the semiconductor element and the wiring line, and
the encapsulation resin covers a region of the wiring front surface excluding a region in which the bonding portion is arranged.

9. The semiconductor device according to claim 1, wherein the wiring line extends in a direction orthogonal to a thickness-wise direction of the encapsulation resin.

10. The semiconductor device according to claim 9, wherein
the encapsulation resin includes
a flat substrate, and
an encapsulation portion formed on the substrate to encapsulate the semiconductor element,
the substrate includes a substrate front surface facing in a same direction as the element front surface of the semiconductor element, and
the wiring line is formed on the substrate front surface.

11. A method for manufacturing a semiconductor device including: a semiconductor element including an element front surface, an element back surface opposite to the element front surface, and an element side surface joining the element front surface and the element back surface; an electrical conductor opposed to the element back surface and including a wiring line on which the semiconductor element is mounted; and an encapsulation resin encapsulating the semiconductor element and the electrical conductor, the wiring line including a wiring front surface opposed to the element back surface and a wiring back surface opposite to the wiring front surface, and the electrical conductor including a terminal extending from the wiring back surface in a direction opposite from the semiconductor element, the method, comprising:
forming a resin layer that covers the element front surface, the element back surface, and the element side surface of the semiconductor element and the wiring front surface of the wiring line, the resin layer including a portion of the encapsulation resin; and
grinding the resin layer so that the element front surface is exposed from the resin layer.

12. The method according to claim 11, wherein in the forming the resin layer, the resin layer is formed by compression molding.

13. The method according to claim 11, wherein in the grinding the resin layer, the resin layer and the semiconductor element are ground.

14. The method according to claim 11, further comprising:
subsequent to the forming the resin layer, exposing a side surface of the terminal by forming a groove in the resin layer to have a depth in a thickness-wise direction of the resin layer; and
forming a plating layer on the exposed side surface of the terminal,
wherein the grinding the resin layer is performed subsequent to the forming the plating layer on the exposed side surface of the terminal.

15. The method according to claim 14, wherein
the resin layer includes a resin front surface, facing in a same direction as the element front surface of the semiconductor element, and a resin back surface opposite to the resin front surface,
the groove is formed from the resin back surface to have a depth in the thickness-wise direction of the resin layer,
in the grinding the resin layer, the resin layer is ground from a side of the resin front surface, and
the groove includes a bottom surface separated from the resin front surface, which is ground in the grinding the resin layer, toward the resin back surface.

16. The method according to claim 15, further comprising:
subsequent to the grinding the resin layer, cutting apart the resin layer through the groove.
